(19) United States
(12) Patent Application Publication
(10) Pub. No.: US 2023/0139176 A1
(43) Pub. Date: May 4, 2023

(54) IMAGING DEVICE AND ELECTRONIC APPARATUS

(71) Applicant: SONY SEMICONDUCTOR SOLUTIONS CORPORATION, Kanagawa (JP)

(72) Inventor: Takashi YOKOYAMA, Kanagawa (JP)

(73) Assignee: SONY SEMICONDUCTOR SOLUTIONS CORPORATION, Kanagawa (JP)

(21) Appl. No.: 17/911,531

(22) PCT Filed: Mar. 17, 2021
(86) PCT No.: PCT/JP2021/010927

§ 371 Date: Sep. 14, 2022

(30) Foreign Application Priority Data
Mar. 31, 2020 (JP) 2020-064019

(51) Int. Cl. H01L 27/146; H04N 25/772; H04N 25/79

(52) U.S. Cl. CPC H01L 27/14636; H01L 27/14612; H01L 27/14643; H04N 25/772; H04N 25/79

(57) ABSTRACT

An imaging device that includes: a first substrate having a first surface and a second surface and including a sensor pixel on a first semiconductor substrate, the sensor pixel performing photoelectric conversion; a second substrate having a third surface and a fourth surface and including a first transistor on a second semiconductor substrate, the first transistor configuring a pixel circuit that outputs a pixel signal based on electric charge outputted from the sensor pixel, the second substrate being stacked on the first substrate with the first surface and the third surface being opposed to each other; and a third substrate having a fifth surface and a sixth surface and including a second transistor on a third semiconductor substrate, the second transistor configuring the pixel circuit, the third substrate being stacked on the second substrate with the fourth surface and the fifth surface being opposed to each other.

### TECHNICAL FIELD

The present disclosure relates to an imaging device having a three-dimensional structure, and to an electronic apparatus that includes the imaging device.

### BACKGROUND ART

The introduction of a miniaturization process and an increase in packaging density have reduced the area of one pixel in an imaging device having a two-dimensional structure. In recent years, to achieve further smaller imaging devices and higher pixel density, imaging devices that each have a three-dimensional structure have been developed. In an imaging device having a three-dimensional structure, for example, a first substrate with a photoelectric converter section PD formed thereon and a second substrate with a charge accumulation capacitor section and multiple MOS transistors formed thereon are attached to each other (see, for example, PTL 1).

### CITATION LIST

### Patent Literature

PTL 1: Japanese Unexamined Patent Application Publication No. 2010-219339

### SUMMARY OF THE INVENTION

Incidentally, a further reduction in pixel size is demanded of an imaging device.

It is desirable to provide an imaging device that makes it possible to reduce the pixel size, and an electronic apparatus that includes the imaging device.

An imaging device according to an embodiment of the present disclosure includes a first substrate, a second substrate, and a third substrate. The first substrate has a first surface and a second surface and includes a sensor pixel on a first semiconductor substrate, the sensor pixel performing photoelectric conversion. The second substrate has a third surface and a fourth surface and includes a first transistor on a second semiconductor substrate, the first transistor configuring a pixel circuit that outputs a pixel signal based on electric charge outputted from the sensor pixel. The second substrate is stacked on the first substrate with the first surface and the third surface being opposed to each other. The third substrate has a fifth surface and a sixth surface and includes a second transistor on a third semiconductor substrate, the second transistor configuring the pixel circuit. The third substrate is stacked on the second substrate with the fourth surface and the fifth surface being opposed to each other.

An electronic apparatus according to an embodiment of the present disclosure includes the imaging device according to the embodiment of the present disclosure described above.

In the imaging device according to the embodiment of the present disclosure and the electronic apparatus according to the embodiment, the first transistor and the second transistor that configure the pixel circuit are formed in respective different substrates (the second substrate and the third substrate), and the second substrate and the third substrate are stacked in order on the first substrate that includes the sensor pixel performing photoelectric conversion. This reduces a formation area of the pixel circuit in a plan view.

### BRIEF DESCRIPTION OF THE DRAWINGS

FIG. 1 is a schematic cross-sectional diagram illustrating a configuration of an imaging device according to a first embodiment of the present disclosure.

FIG. 2 is a diagram illustrating an example of an equivalent circuit of the imaging device illustrated in FIG. 1.

FIG. 3 is a schematic plan diagram illustrating an example of a layout of a first substrate illustrated in FIG. 1.

FIG. 4 is a schematic plan diagram illustrating an example of a layout of a lower wiring layer in a second substrate illustrated in FIG. 1.

FIG. 5 is a schematic plan diagram illustrating an example of an upper wiring layer in the second substrate illustrated in FIG. 1.

FIG. 6 is a schematic plan diagram illustrating an example of a layout of a lower wiring layer in a third substrate illustrated in FIG. 1.

FIG. 7 is a schematic plan diagram illustrating an example of an upper wiring layer in the third substrate illustrated in FIG. 1.

FIG. 8 is a perspective view of a transistor having a three-dimensional structure.

FIG. 9A is a schematic cross-sectional diagram describing an example of a manufacturing process of the imaging device illustrated in FIG. 1.

FIG. 9B is a schematic cross-sectional diagram illustrating a process following FIG. 9A.

FIG. 9C is a schematic cross-sectional diagram illustrating a process following FIG. 9B.

FIG. 9D is a schematic cross-sectional diagram illustrating a process following FIG. 9C.

FIG. 9E is a schematic cross-sectional diagram illustrating a process following FIG. 9D.

FIG. 9F is a schematic cross-sectional diagram illustrating a process following FIG. 9E.

FIG. 9G is a schematic cross-sectional diagram illustrating a process following FIG. 9F.

FIG. 10A is a schematic cross-sectional diagram describing another example of the manufacturing process of the imaging device illustrated in FIG. 1.

FIG. 10B is a schematic cross-sectional diagram illustrating a process following FIG. 10A.

FIG. 10C is a schematic cross-sectional diagram illustrating a process following FIG. 10B.

FIG. 10D is a schematic cross-sectional diagram illustrating a process following FIG. 10C.

FIG. 10E is a schematic cross-sectional diagram illustrating a process following FIG. 10D.

FIG. 10F is a schematic cross-sectional diagram illustrating a process following FIG. 10E.

FIG. 11 is a schematic cross-sectional diagram illustrating a configuration of an imaging device according to a second embodiment of the present disclosure.

FIG. 12 is a diagram illustrating an example of an equivalent circuit of the imaging device illustrated in FIG. 11.

FIG. 13 is a schematic cross-sectional diagram illustrating a configuration of an imaging device according to a third embodiment of the present disclosure.

FIG. 14 is a diagram illustrating an example of an equivalent circuit of the imaging device illustrated in FIG. 13.

FIG. 15 is a schematic cross-sectional diagram illustrating a configuration of an imaging device according to a fourth embodiment of the present disclosure.

FIG. 16 is a schematic cross-sectional diagram illustrating a configuration of an imaging device according to a fifth embodiment of the present disclosure.

FIG. 17 is a diagram illustrating an example of an equivalent circuit of an imaging device according to a sixth embodiment of the present disclosure.

FIG. 18 is a schematic cross-sectional diagram illustrating an example of a cross-sectional configuration of the imaging device illustrated in FIG. 17.

FIG. 19 is a schematic cross-sectional diagram illustrating another example of the cross-sectional configuration of the imaging device illustrated in FIG. 16 as Modification Example 1.

FIG. 20 is a schematic cross-sectional diagram illustrating another example of the cross-sectional configuration of the imaging device illustrated in FIG. 16 as Modification Example 2.

FIG. 21 is a schematic cross-sectional diagram illustrating another example of the cross-sectional configuration of the imaging device illustrated in FIG. 16 as Modification Example 3.

FIG. 22 is a schematic cross-sectional diagram illustrating another example of the cross-sectional configuration of the imaging device illustrated in FIG. 16 as Modification Example 3.

FIG. 23 is a schematic cross-sectional diagram illustrating another example of the cross-sectional configuration of the imaging device illustrated in FIG. 16 as Modification Example 4.

FIG. 24 is a schematic cross-sectional diagram illustrating another example of the cross-sectional configuration of the imaging device illustrated in FIG. 16 as Modification Example 5.

FIG. 25 is an exploded perspective diagram illustrating a schematic configuration of an imaging device according to a seventh embodiment of the present disclosure.

FIG. 26 is a schematic cross-sectional diagram illustrating an example of a configuration of the imaging device illustrated in FIG. 25.

FIG. 27 is a diagram illustrating another example of a circuit configuration of the imaging device illustrated in FIG. 25.

FIG. 28 is an exploded perspective diagram illustrating a schematic configuration of an imaging device having the circuit configuration illustrated in FIG. 27.

FIG. 29 is a diagram illustrating an example of a schematic configuration of an imaging system including the imaging device according to any of the first to seventh embodiments and Modification Examples 1 to 5 described above.

FIG. 30 is a diagram illustrating an example of an imaging procedure of the imaging system in FIG. 29.

FIG. 31 is a block diagram depicting an example of schematic configuration of a vehicle control system.

FIG. 32 is a diagram of assistance in explaining an example of installation positions of an outside-vehicle information detecting section and an imaging section.

FIG. 33 is a view depicting an example of a schematic configuration of an endoscopic surgery system.

FIG. 34 is a block diagram depicting an example of a functional configuration of a camera head and a camera control unit (CCU).

FIG. 35 is a schematic cross-sectional diagram illustrating an example of a cross-sectional configuration of an imaging device as a modification example of the present disclosure.

### MODES FOR CARRYING OUT THE INVENTION

In the following, some embodiments of the present disclosure are described in detail with reference to the drawings. It is to be noted that the following description is a specific example of the present disclosure, and the present disclosure is not limited to the following embodiments. In addition, the arrangement, dimensions, dimension ratios, and the like of components illustrated in the drawings should not be construed as limiting the present disclosure. It is to be noted that the description is given in the following order.

1. First Embodiment (An example of an imaging device in which multiple pixel transistors that configure a pixel circuit are formed separately in a second substrate and a third substrate)

1-1. Schematic Configuration of Imaging Device

1-2. Specific Configuration of Imaging Device

1-3. Method of Manufacturing Imaging Device

1-4. Workings and Effects

2. Second Embodiment (An example of an imaging device in which an amplification transistor is provided in the second substrate, and a reset transistor and a selection transistor are provided in the third substrate)
3. Third Embodiment (An example of an imaging device in which the amplification transistor, the reset transistor, and the selection transistor are separately provided in the second substrate, the third substrate, and the fourth substrate, respectively)
4. Fourth Embodiment (An example of an imaging device in which gate electrodes of the pixel transistors include metal)
5. Fifth Embodiment (An example in which the gate electrode of the amplification transistor and a source/drain region of the reset transistor are directly coupled to respective pad electrodes)
6. Sixth Embodiment (An example of an imaging device in which a capacitor and a switching transistor that switches between coupling and decoupling of the capacitor are further formed)

### 7. Modification Examples

7-1. Modification Example 1 (An example in which a capacitor having a MIM structure is provided)

7-2. Modification Example 2 (An example in which a capacitor having the MIM structure is provided)

7-3. Modification Example 3 (An example in which the capacitor is provided in the third substrate)

7-4. Modification Example 4 (An example in which the capacitor and the switching transistor are provided in the third substrate)

7-5. Modification Example 5 (An example in which the capacitor is provided on a bonding surface of the third substrate to be bonded to the second substrate)

8. Seventh Embodiment (An example of an imaging device in which a fifth substrate provided with a logic circuit is further stacked)

9. Application Example

10. Practical Application Examples

### 1. First Embodiment

### (1-1. Schematic Configuration of Imaging Device)

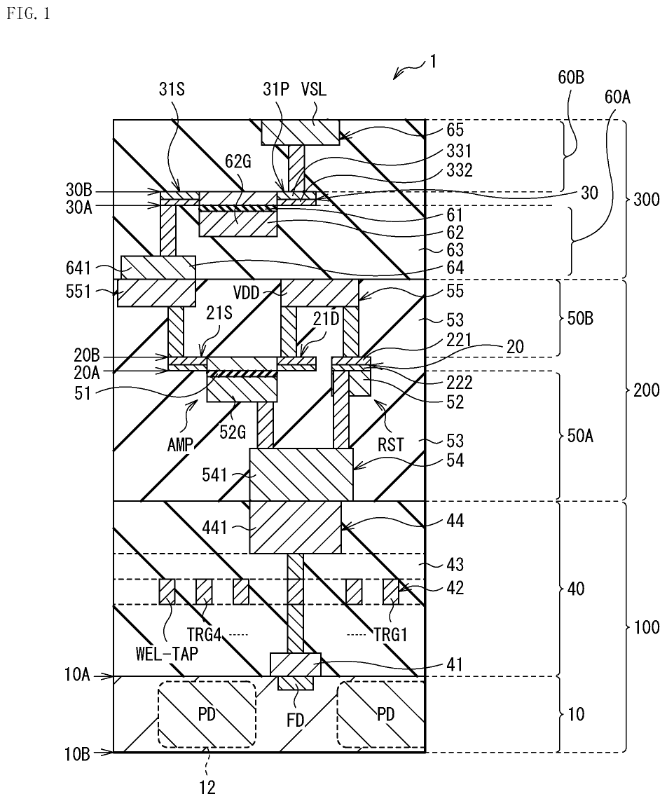

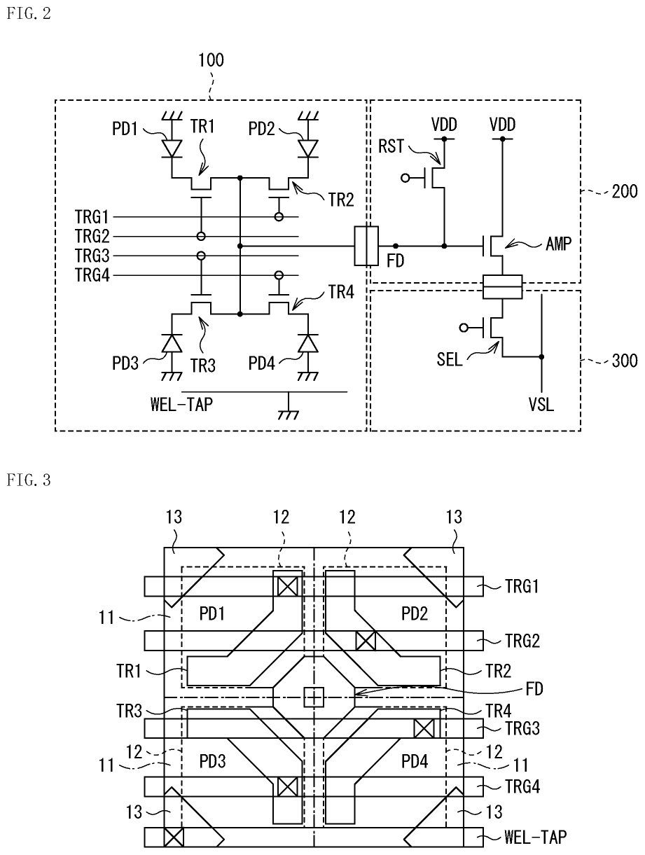

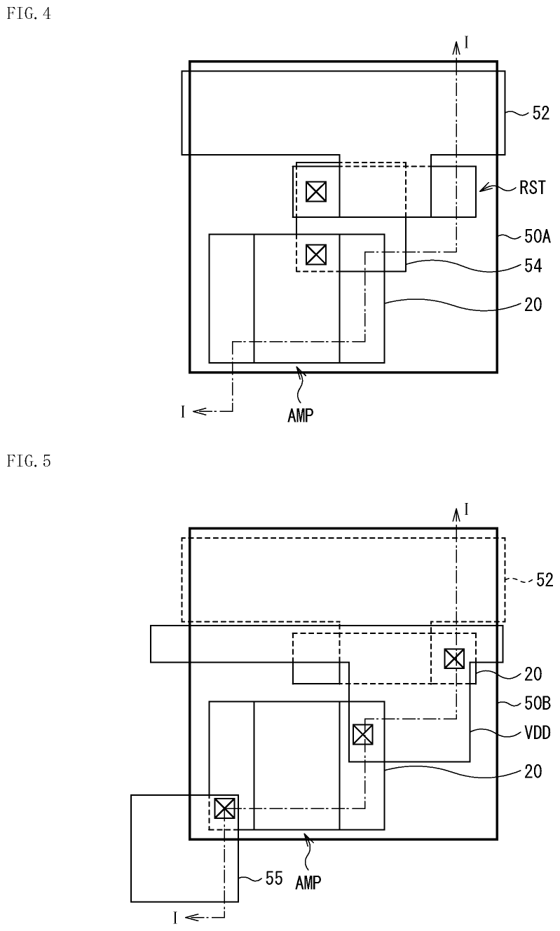

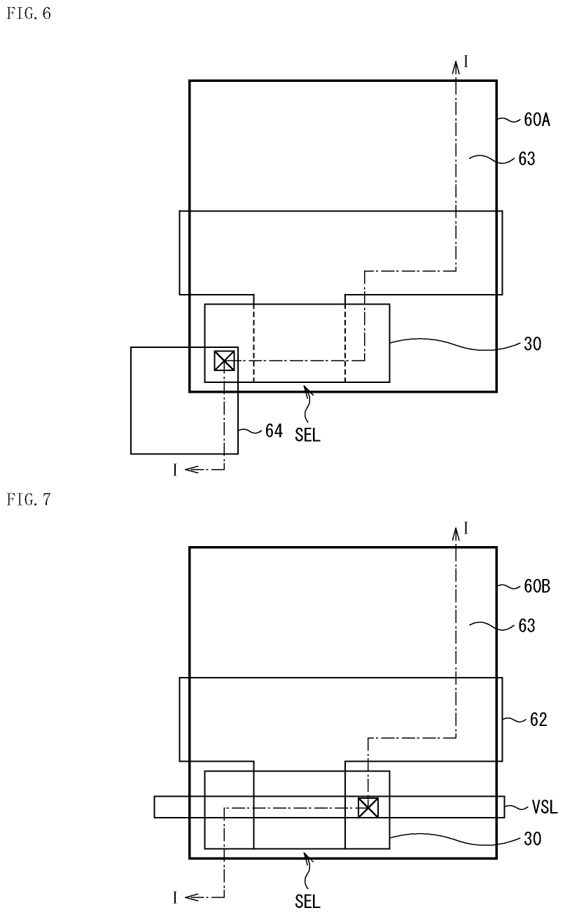

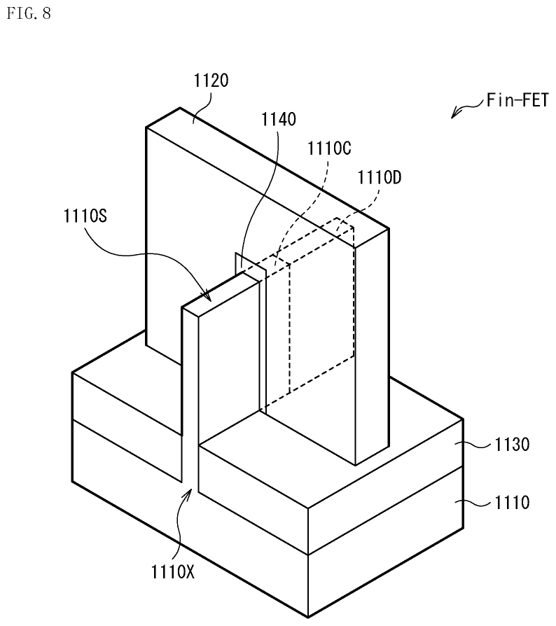

FIG. 1 schematically illustrates an example of a cross-sectional configuration of an imaging device (imaging device 1) according to a first embodiment of the present disclosure. FIG. 2 illustrates an example of an equivalent circuit of the imaging device 1 illustrated in FIG. 1. FIG. 3 illustrates an example of a layout of a first substrate 100 of the imaging device 1 illustrated in FIG. 1. FIGS. 4 and 5 each illustrate an example of a wiring layout on a second substrate 200 side of the imaging device 1 illustrated in FIG. 1. FIGS. 6 and 7 each illustrate an example of the wiring layout on the second substrate 200 side illustrated in FIG. 1. It is to be noted that FIG. 1 illustrates a cross section of the imaging device 1 corresponding to line I-I illustrated in each of FIGS. 4 to 7. The imaging device 1 includes three substrates (the first substrate 100, the second substrate 200, and a third substrate 300), for example. The imaging device 1 is an imaging device having a three-dimensional structure in which the first substrate 100, the second substrate 200, and the third substrate 300 are stacked in this order.

The first substrate 100 includes a semiconductor substrate 10 and a wiring layer 40. The semiconductor substrate 10 has a first surface (a front surface) 10A and a second surface (a back surface) 10B that are opposed to each other. The wiring layer 40 is provided on the first surface 10A of the semiconductor substrate 10. The second substrate 200 includes a semiconductor substrate 20 and a wiring layer 50. The semiconductor substrate 20 has a first surface (a front surface) 20A and a second surface (a back surface) 20B that are opposed to each other, and includes, as the wiring layer 50, a lower wiring layer 50A and an upper wiring layer 50B that are provided on the first surface 20A side and the second surface 20B side, respectively, of the semiconductor substrate 20. The third substrate 300 includes a semiconductor substrate 30 and a wiring layer 60. The semiconductor substrate 30 has a first surface (a front surface) 30A and a second surface (a back surface) 30B that are opposed to each other, and includes, as the wiring layer 60, a lower wiring layer 60A and an upper wiring layer 60B that are provided on the first surface 30A side and the second surface 30B side, respectively, of the semiconductor substrate 10.

In the imaging device 1, the first substrate 100 and the second substrate 200 are stacked with the wiring layer 40 and the lower wiring layer 50A interposed therebetween, the wiring layer 40 being provided on the first surface 10A of the semiconductor substrate 10, the lower wiring layer 50A being provided on the first surface 20A of the semiconductor substrate 20. That is, the first substrate 100 and the second substrate 200 are stacked face to face. The second substrate 200 and the third substrate 300 are stacked with the upper wiring layer 50B and the lower wiring layer 60A interposed therebetween, the upper wiring layer 50B being provided on the second surface 20B of the semiconductor substrate 20, the lower wiring layer 60A being provided on the first surface 30A of the semiconductor substrate 30. That is, the second substrate 200 and the third substrate 300 are stacked face to back.

The first substrate 100 includes multiple sensor pixels 11 on the semiconductor substrate 10, the sensor pixels 11 performing photoelectric conversion. Specifically, the first substrate 100 is provided with a photodiode PD (a light-receiving element 12), a floating diffusion FD, a well tap 13, and a transfer transistor TR. The second substrate 200 and the third substrate are each provided with a pixel circuit that outputs a pixel signal based on electric charge outputted from the sensor pixel 11. The pixel circuit includes, for example, three transistors, specifically, an amplification transistor AMP, a reset transistor RST, and a selection transistor SEL.

Upon turning-on of the transfer transistor TR, the transfer transistor TR transfers electric charge of the photodiode PD to the floating diffusion FD.

The reset transistor RST resets an electric potential of the floating diffusion FD to a predetermined electric potential. Upon turning-on of the reset transistor RST, the reset transistor RST resets the electric potential of the floating diffusion FD to a power supply line VDD.

The selection transistor SEL controls a timing at which the pixel signal is outputted from the pixel circuit.

The amplification transistor AMP generates, as the pixel signal, a signal of a voltage corresponding to the level of electric charge held by the floating diffusion FD. The amplification transistor AMP configures a source-follower-type amplifier and outputs the pixel signal of a voltage corresponding to the level of electric charge generated in the photodiode PD (the light-receiving element 12). Upon turning-on of the selection transistor SEL, the amplification transistor AMP amplifies the electric potential of the floating diffusion FD and outputs a voltage corresponding to the electric potential to a logic circuit, which will be described later, through a vertical signal line VSL.

In the imaging device 1 of the present embodiment, the amplification transistor AMP and the reset transistor RST, for example, of the amplification transistor AMP, the reset transistor RST, and the selection transistor SEL that configure the pixel circuit, are each provided on the semiconductor substrate 20 of the second substrate 200, and the selection transistor SEL is provided on the semiconductor substrate 30 of the third substrate 300.

The semiconductor substrate 10 corresponds to a specific example of a “first semiconductor substrate” according to the present disclosure. The first surface 10A corresponds to a specific example of a “first surface” according to the present disclosure and the second surface 10B corresponds to a specific example of a “second surface” according to the present disclosure. The semiconductor substrate 20 corresponds to a specific example of a “second semiconductor substrate” according to the present disclosure. The first surface 20A corresponds to a specific example of a “third surface” according to the present disclosure and the second surface 20B corresponds to a specific example of a “fourth surface” according to the present disclosure. The semiconductor substrate 30 corresponds to a specific example of a “third semiconductor substrate” according to the present disclosure. The first surface 30A corresponds to a specific example of a “fifth surface” according to the present disclosure and the second surface 30B corresponds to a specific example of a “sixth surface” according to the present disclosure. The amplification transistor AMP and the reset transistor each correspond to a specific example of a “first transistor” according to the present disclosure, and the selection transistor SEL corresponds to a specific example of a “second transistor” according to the present disclosure.

### (1-2. Specific Configuration of Imaging Device)

In the imaging device 1, for example, the multiple sensor pixels 11 are arranged repeatedly in an array on the semiconductor substrate 10 included in the first substrate 100. For example, a pixel-sharing unit including the multiple sensor pixels 11 serves as a unit of repetition. The pixel-sharing units are repeatedly arranged in an array having a row direction and a column direction. In the present embodiment, the pixel-sharing unit includes four sensor pixels 11, and the four sensor pixels 11 share one floating diffusion FD. One pixel circuit is formed for every four sensor pixels 11. The respective sensor pixels 11 include mutually common components. In FIG. 3, to distinguish the components of the respective sensor pixels 11 from each other, an identification number (1, 2, 3, or 4) is assigned to the end of the symbol of the photodiode PD configuring the light-receiving element 12 provided in each of the sensor pixels 11. In the following, in a case where the components of the respective sensor pixels 11 have to be distinguished from each other, an identification number (1, 2, 3, or 4) consistent with the identification number at the end of the symbol of the photodiode PD is assigned to the end of the symbol of a component of each of the sensor pixels 11. However, in a case where there is no need for distinguishing the components of the respective sensor pixels 11 from each other, the identification number at the end of the symbol of a component of each of the sensor pixels 11 is omitted.

In each of the sensor pixels 11, for example, a cathode of the photodiode PD (the light-receiving element 12) is electrically coupled to a source of the transfer transistor TR, and an anode of the photodiode PD (the light-receiving element 12) is electrically coupled to a reference potential line (e.g., a ground). A drain of the transfer transistor TR is electrically coupled to the floating diffusion FD.

The floating diffusion FD shared by the four sensor pixels 11 is electrically coupled to an input end of the common pixel circuit. Specifically, the floating diffusion FD is electrically coupled to a gate of the amplification transistor AMP and a source of the reset transistor RST. A drain of the reset transistor RST is coupled to the power supply line VDD, and a gate of the reset transistor RST is coupled to, for example, a drive signal line, although not illustrated. A drain of the amplification transistor AMP is coupled to the power supply line VDD, and a source of the amplification transistor AMP is coupled to a drain of the selection transistor SEL. A source of the selection transistor SEL is coupled to the vertical signal line VSL, and a gate of the selection transistor SEL is coupled to, for example, the drive signal line, although not illustrated.

The semiconductor substrate 10 is configured by a silicon substrate, for example. The semiconductor substrate 10 includes the photodiode PD (the light-receiving element 12), the floating diffusion FD, the well tap 13, and the transfer transistor TR on the first surface 10A side, for example.

The semiconductor substrate 20 is configured by a silicon substrate, for example. Although not illustrated, the semiconductor substrate 20 is divided into multiple ones by an element separation region having a STI (Shallow Trench Isolation) structure, or a DTI (Deep Trench Isolation) or FTI (Full Trench Isolation) structure, for example. The individual semiconductor substrates 20 divided by the STI or the like are each provided with the amplification transistor AMP and the reset transistor RST as described above. The amplification transistor AMP and the reset transistor RST each have a planar structure, for example, and each include a gate electrode 52G, a source region 21S, and a drain region 21D.

The gate electrode 52G is provided on the first surface 20A side of the semiconductor substrate 20 with a gate insulating film 51 interposed between the gate electrode 52G and the first surface 20A. The gate insulating film 51 includes, for example, silicon oxide (SiO₂) or the like. The gate electrode 52G includes polysilicon (Poly-Si), for example. The source region 21S and the drain region 21D are provided across a channel region opposed to the gate electrode 52G from each other. The source region 21S and the drain region 21D each have a stacked structure of a diffusion layer 211 and a low-resistance layer 212 provided on the semiconductor substrate 20. The diffusion layer 211 includes impurities diffused therein, for example. The low-resistance layer 212 includes a silicide formed with use of a Salicide (Self Aligned Silicide) process, such as cobalt silicide (CoSi2) or nickel silicide (NiSi), for example.

The semiconductor substrate 30 is configured by a silicon substrate, for example, and is divided into multiple ones by an element separation region having, for example, the STI structure, or the DTI or FTI structure, similarly to the semiconductor substrate 20 described above. The semiconductor substrate 30 is provided with the selection transistor SEL, as described above. Similarly to the amplification transistor AMP and the reset transistor RST, the selection transistor SEL has a planar structure, and includes a gate electrode 62G, a source region 31S, and a drain region 31D.

The gate electrode 62G is provided on the first surface 30A side of the semiconductor substrate 30 with a gate insulating film 61 interposed between the gate electrode 62G and the first surface 30A. The gate insulating film 61 includes, for example, silicon oxide (SiO₂) or the like. The gate electrode 62G includes polysilicon (Poly-Si), for example. The source region 31S and the drain region 31D are provided across a channel region opposed to the gate electrode 62G from each other. The source region 31S and the drain region 31D each have a stacked structure of a diffusion layer 311 and a low-resistance layer 312 provided on the semiconductor substrate 20. The diffusion layer 311 includes impurities diffused therein, for example. The low-resistance layer 312 includes a silicide formed with use of a Salicide process, such as cobalt silicide (CoSi2) or nickel silicide (NiSi), for example.

It is to be noted that the amplification transistor AMP, the reset transistor RST, and the selection transistor SEL are not limited to those having a planar structure, and may have a three-dimensional structure. FIG. 8 illustrates a Fin-FET as an example of a transistor having a three-dimensional transistor structure. The Fin-FET includes, for example, a fin 1110X and a gate electrode 1120. The fin 1110X includes silicon (Si) and has a source region 11105 and a drain region 1110D.

The fin 1110X is flat plate-shaped. For example, multiple fins 1110X are provided to stand on a silicon substrate 1110, for example. The multiple fins 1110X each extend in an X direction, for example, and are disposed side by side in a Y-axis direction. An insulating film 1130 including SiO₂, for example, is provided on the silicon substrate 1110, and the fin 110X is provided to stand and penetrate through the insulating film 1130. In other words, a portion of the fin 110X is embedded in the insulating film 1130. A side surface and a top surface of the film 1110X exposed from the insulating film 1130 are covered with a gate insulating film 1140 including, for example, HfSiO, HfSiON, TaO, TaON, or the like. The gate electrode 1120 extends across the fin 1110X in a Z direction intersecting the direction (the X direction) in which the fin 1110X extends. A channel region 1110C is formed at a portion of the fin 1110X at which the fin 1110X and the gate electrode 1120 intersect. The source region 1110A and the drain region 1110D are formed at opposite ends with the channel region 1110C interposed therebetween.

The Fin-FET makes it possible to increase a channel width (W) and a channel length (L) of the transistor by the height of the fin 1110X. Accordingly, employing a transistor having a three-dimensional structure such as the Fin-FET as each of the amplification transistor AMP, the reset transistor RST, and the selection transistor SEL makes it possible to achieve an increased channel width (W) and an increased channel length (L) with the same layout area, as compared with a case of the planar structure.

Other than the above, the amplification transistor AMP, the reset transistor RST, and the selection transistor SEL may each have a full-depletion transistor structure. This makes it possible to form the pixel transistors having good voltage linearity.

The wiring layer 40 includes a wiring line 41 and a wiring line 42 that are formed within an interlayer insulating layer 43, for example. The wiring line 41 is coupled to the floating diffusion FD. The wiring line 42 includes the gates (e.g., TRG1, TRG2, TRG3, and TRG4) of the transfer transistors TR and the like. The wiring line 41 and the wiring line 42 are provided in this order, within the interlayer insulating layer 43, from the first surface 10A side of the semiconductor substrate 10. One or multiple pad electrodes 44 to be used for bonding to the second electrode, for example, are exposed at a surface of the interlayer insulating layer 43. The wiring line 41 and the wiring line 42, and the wiring line 42 and one pad electrode 44 (a pad electrode 441) are electrically coupled to each other through a via, for example.

The lower wiring layer 50A is provided on the first surface 20A side of the semiconductor substrate 20, and includes a wiring line 52 within an interlayer insulating layer 53, for example. The wiring line 52 includes the respective gate electrodes 52G of the amplification transistor AMP and the reset transistor RST. One or multiple pad electrodes 54 to be used for bonding to the first substrate 100, for example, are exposed at a surface of the interlayer insulating layer 53 facing the first substrate 100. In the lower wiring layer 50A, the gate electrode 52G of the amplification transistor AMP and the source region 21S of the reset transistor RST are coupled to one pad electrode 54 (a pad electrode 541) through respective vias. That is, the gate electrode 52G of the amplification transistor AMP and the source region 21S of the reset transistor RST are electrically coupled to each other through the pad electrode 541 and the vias.

The upper wiring layer 50B is provided on the second surface 20B side of the semiconductor substrate 20. The upper wiring layer 50B includes, for example, the interlayer insulating layer 53 continuous from the lower wiring layer 50A, and one or multiple pad electrodes 55 that are exposed at a surface of the interlayer insulating layer 53 facing the third substrate 300 and that are to be used for bonding to the third substrate 300, for example. In the upper wiring layer 50B, the source region 21S of the amplification transistor AMP and one pad electrode 55 (a pad electrode 551) are electrically coupled to each other through a via. In addition, one pad electrode 55 is used as the power supply line VDD, to which the drain region 21D of the amplification transistor AMP and the drain region 21D of the reset transistor RST are electrically coupled through respective vias.

The lower wiring layer 60A is provided on the first surface 30A side of the semiconductor substrate 30, and includes a wiring line 62 within an interlayer insulating layer 63, for example. The wiring line 62 includes the gate electrode 62G of the selection transistor SEL. One or multiple pad electrodes 64 to be used for bonding to the second substrate 200, for example, are exposed at a surface of the interlayer insulating layer 63 facing the second substrate 200. In the lower wiring layer 60A, the source region 31S of the selection transistor SEL is coupled to one pad electrode 64 (a pad electrode 641) through a via.

The upper wiring layer 60B is provided on the second surface 30B side of the semiconductor substrate 30. The upper wiring layer 60B includes, for example, the interlayer insulating layer 63 continuous from the lower wiring layer 60A, and one or multiple pad electrodes 65 that are exposed at a surface of the interlayer insulating layer 63 opposite to the surface thereof facing the third substrate 300. One pad electrode 65 is used as the vertical signal line VSL, to which the drain region 31D of the selection transistor SEL is electrically coupled through a via.

The wiring line 41 and the pad electrodes 44, 54, 55, 64, and 65 provided in the wiring layers 40, 50A, 50B, 60A, and 60B may each include a metal material that includes, for example, copper (Cu) as a main material. The pad electrodes 44, 54, 55, 64, and 65 are formed as copper electrodes, for example, and a barrier metal including, for example, titanium nitride (TiN) or the like is formed therearound. It is to be noted that the pad electrodes 44, 54, 55, 64, and 65 may include another metal to the extent that the performance as the copper electrode will not be degraded. The vias coupling the wiring lines to each other may include, for example, tungsten (W) or copper (Cu).

In the present embodiment, the first substrate 100 and the second substrate 200 are coupled to each other and the second substrate 200 and the third substrate 300 are coupled to each other by means of bonding between the respective pad electrodes. Specifically, the first substrate 100 and the second substrate 200 are attached to each other, with the first surface 10A of the semiconductor substrate 10 and the first surface 20A of the semiconductor substrate 20 being opposed to each other, by bonding together the one or multiple pad electrodes 44 and the one or multiple pad electrodes 54 exposed at the respective surfaces of the wiring layer 40 and the lower wiring layer 50A provided on the first surface 10A and the first surface 20A, respectively. The second substrate 200 and the third substrate 300 are attached to each other, with the second surface 20B of the semiconductor substrate 20 and the first surface 30A of the semiconductor substrate 30 being opposed to each other, by bonding together the one or multiple pad electrodes 45 and the one or multiple pad electrodes 64 exposed at the respective surfaces of the upper wiring layer 50B and the lower wiring layer 60A provided on the second surface 20B and the first surface 30A, respectively.

### (1-3. Method of Manufacturing Imaging Device)

It is possible to manufacture the imaging device 1 of the present embodiment in the following manner, for example.

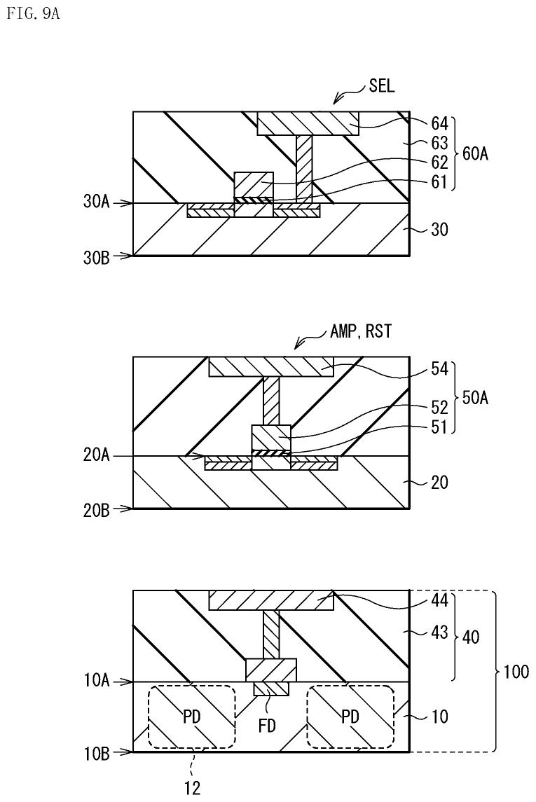

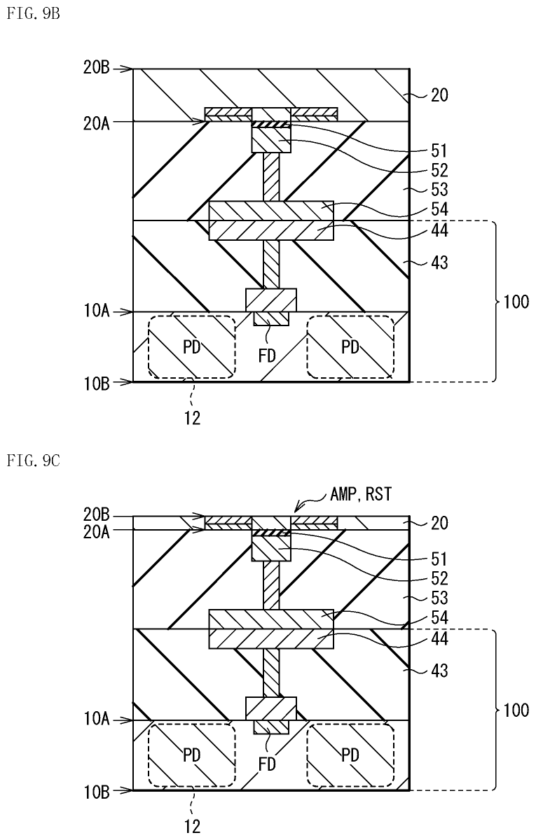

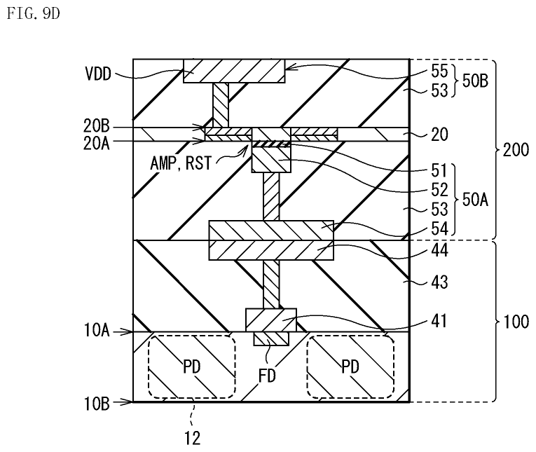

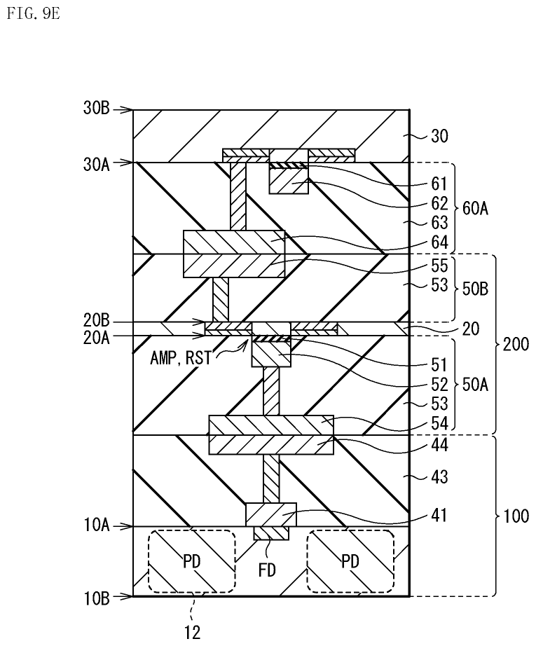

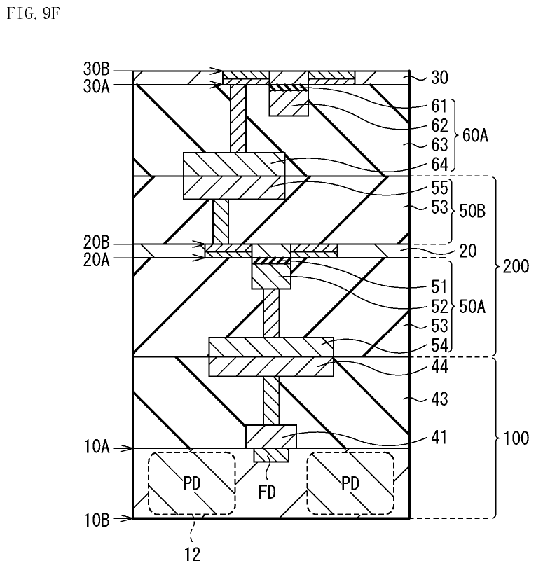

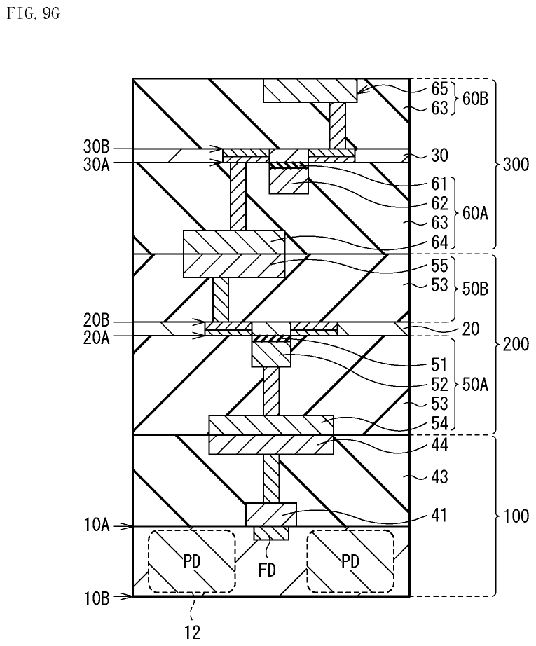

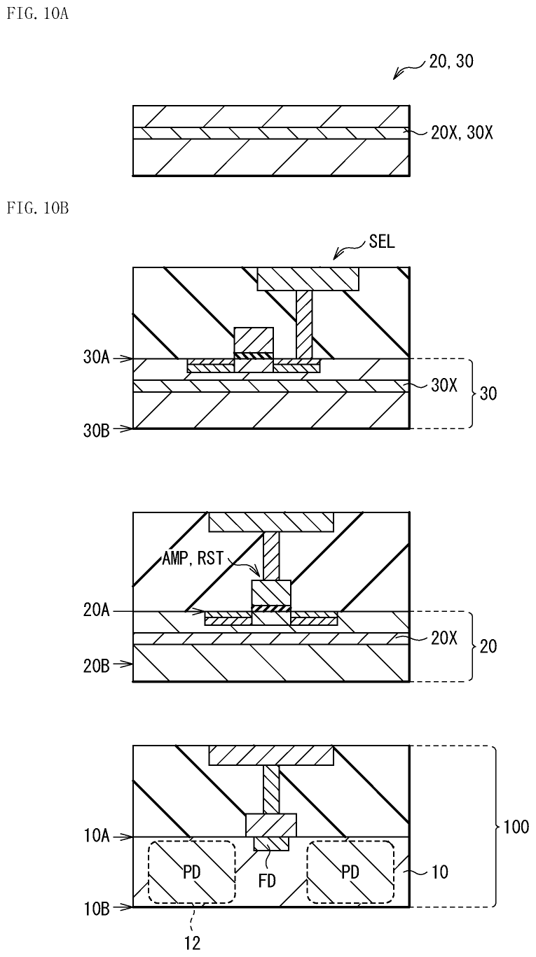

First, as illustrated in FIG. 9A, the wiring layer 40 of the first substrate 100, the lower wiring layer 50A, and the lower wiring layer 61A are formed on respective different substrates (the semiconductor substrates 10, 20, and 30), and a high-temperature activation treatment is performed.

Subsequently, as illustrated in FIG. 9B, the pad electrode 44 exposed at the surface of the wiring layer 40 and the pad electrode 54 exposed at the surface of the lower wiring layer 50A are bonded to each other in a face-down manner. Next, as illustrated in FIG. 9C, the semiconductor substrate 20 is reduced in thickness from the second surface 20B side by chemical mechanical polishing (CMP), for example.

Subsequently, as illustrated in FIG. 9D, the upper wiring layer 50B is formed on the second surface 20B of the semiconductor substrate 20. The second substrate 200 is thereby formed. Next, as illustrated in FIG. 9E, the pad electrode 55 exposed at the surface of the upper wiring layer 50B and the pad electrode 64 exposed at the surface of the lower wiring layer 60A are bonded to each other in a face-down manner.

Subsequently, as illustrated in FIG. 9F, the semiconductor substrate 30 is reduced in thickness from the second surface 30B side by CMP, for example. Thereafter, as illustrated in FIG. 9G, the upper wiring layer 60B is formed on the second surface 30B of the semiconductor substrate 30. The third substrate 300 is thereby formed. The imaging device 1 illustrated in FIG. 1 is completed thus.

It is to be noted that in the method described above, by way of example, the semiconductor substrates 20 and 30 are reduced in thickness by, for example, CMP; however, using the following method makes it possible to reuse the silicon substrate.

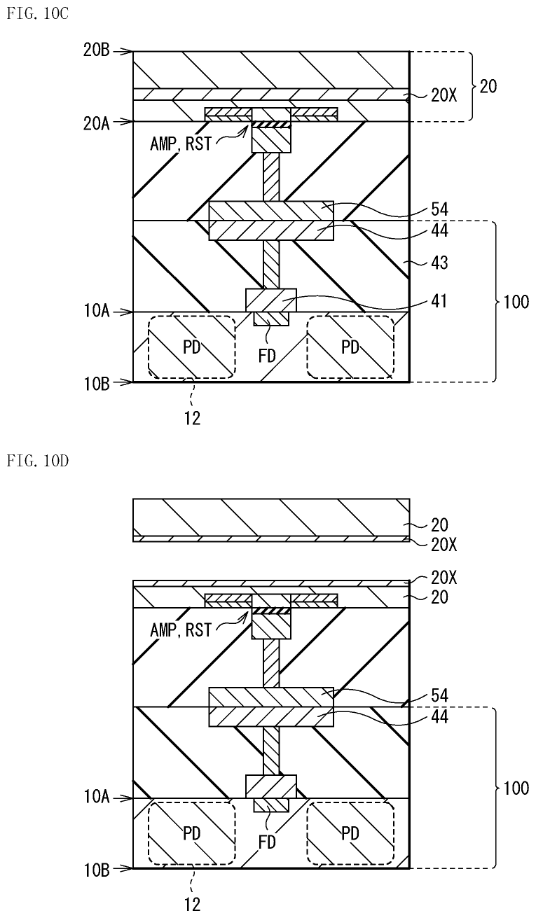

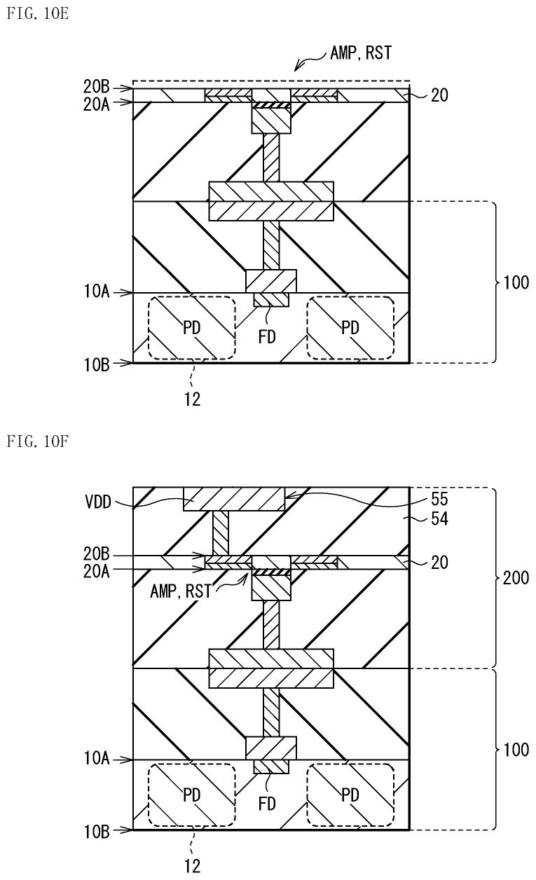

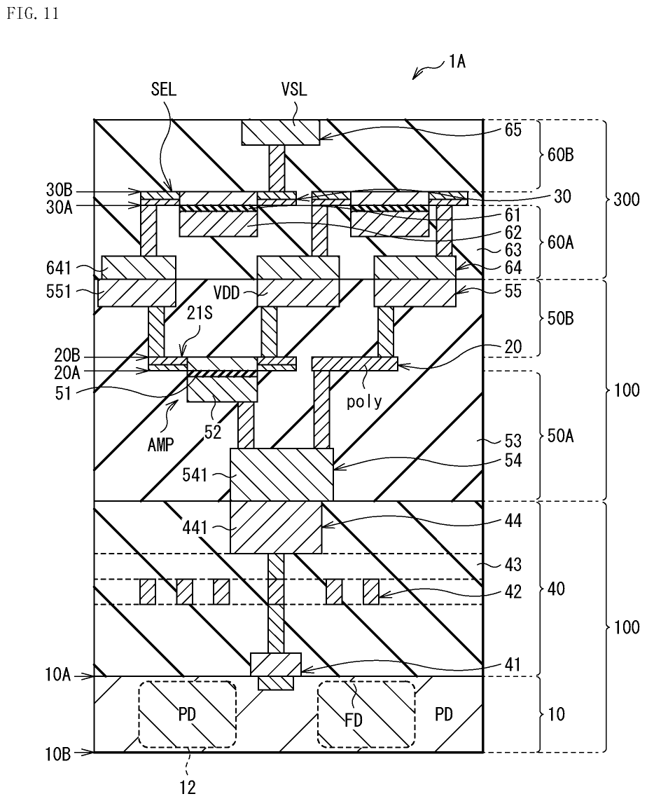

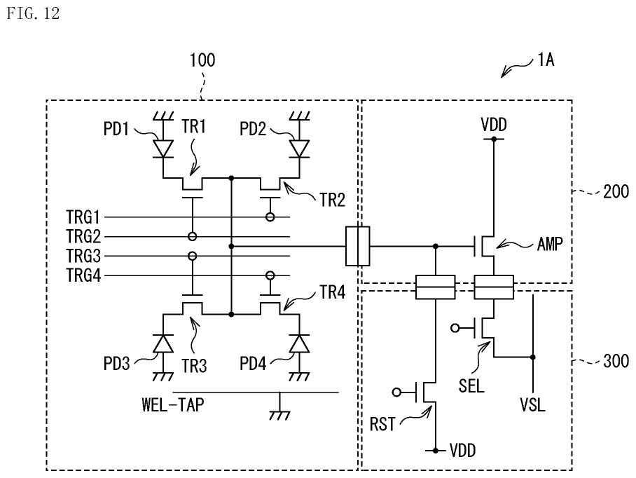

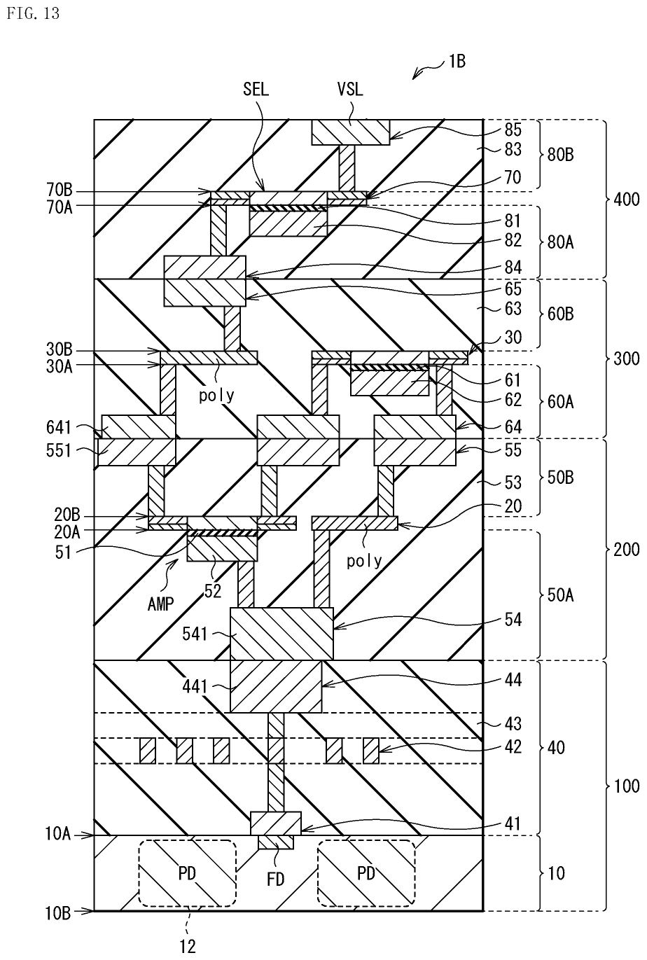

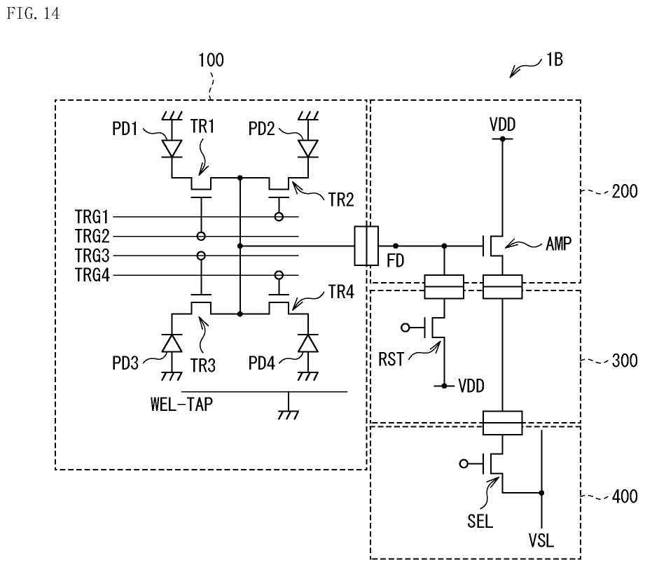

First, for example, hydrogen ions are injected into the semiconductor substrates 20 and 30 to thereby form peel-off layers 20X and 30X in the respective substrates, as illustrated in FIG. 10A. Subsequently, as illustrated in FIG. 10B, the wiring layer 40 is formed on the first surface 10A of the semiconductor substrate 10, the lower wiring layer 50A is formed on the first surface 20A of the semiconductor substrate 20, the lower wiring layer 61A is formed on the first surface 30A of the semiconductor substrate 30, and a high-temperature activation treatment is performed.

Next, as illustrated in FIG. 10C, the pad electrode 44 exposed at the surface of the wiring layer 40 of the first substrate 100 and the pad electrode 54 exposed at the surface of the lower wiring layer 50A are bonded to each other in a face-down manner. Subsequently, as illustrated in FIG. 10D, the semiconductor substrate 20 on the peel-off layer 20X is peeled off. Next, as illustrated in FIG. 10E, the remaining semiconductor substrate 20 is reduced in thickness by, for example, CMP into a predetermined thickness.

Thereafter, as illustrated in FIG. 10F, the upper wiring layer 50B is formed by a method similar to that in the manufacturing method described above, and then the pad electrode 55 exposed at the surface of the upper wiring layer 50B of the second substrate 200 and the pad electrode 64 exposed at the surface of the lower wiring layer 60A are bonded to each other. Subsequently, similarly to the semiconductor substrate 20, the semiconductor substrate 30 on the peel-off layer 30X is peeled off, and thereafter the remaining semiconductor substrate 30 is reduced in thickness by, for example, CMP into a predetermined thickness. Next, the upper wiring layer 60B is formed on the second surface 30B of the semiconductor substrate 30. The imaging device 1 illustrated in FIG. 1 is completed thus.

### (1-4. Workings and Effects)

In the imaging device 1 according to the present embodiment, of the amplification transistor AMP, the reset transistor RST, and the selection transistor SEL that configure the pixel circuit, the amplification transistor AMP and the reset transistor RST are provided in the second substrate 200 and the selection transistor SEL is provided in the third substrate 300. This reduces the formation area of the pixel circuit in a plan view. This will be described in the following.

As described above, the introduction of a miniaturization process and an increase in packaging density have reduced the area of one pixel in an imaging device having a two-dimensional structure. In recent years, to achieve further smaller imaging devices and higher pixel density, imaging devices that each have a three-dimensional structure have been developed. For an imaging device having a three-dimensional structure, as the pixel size is reduced with an increase in the number of pixels, consideration is advancing regarding mounting a pixel transistor on a substrate different from a sensor substrate.

However, in a case where the pixel miniaturization advances further in the future, it is difficult to reduce the area of the pixel transistor in accordance with a general scaling law because of difficulty in reducing the power supply voltage of pixel use. In addition, there is an issue that, from the viewpoint of noise, a great reduction in area is not desirable because a larger area is advantageous for a ratio (W/L) of the channel width (W) to the channel length (L) of the pixel transistor.

To cope with this, in the present embodiment, the multiple transistors that configure the pixel circuit are formed separately in different substrates. Specifically, the amplification transistor AMP and the reset transistor RST are formed in the second substrate 200, and the selection transistor SEL is formed in the third substrate 300. This makes it possible to reduce the formation area of the pixel circuit in a plan view.

By virtue of the above, the imaging device 1 according to the present embodiment makes it possible to reduce the pixel size without reducing the formation areas of the amplification transistor AMP, the reset transistor RST, and the selection transistor SEL that configure the pixel circuit.

In addition, in a case of forming the pixel transistors in multiple substrates and stacking the respective substrates as in the present embodiment, activation of the transistors is typically performed at each increase in the number of substrates. The activation of the transistors is performed with a high-temperature process, and therefore there is a possibility of degradation in the characteristics of the sensor pixels and the transistors formed in lower substrates.

To cope with this, in the present embodiment, the amplification transistor AMP and the reset transistor RST, and the selection transistor SEL are formed on the respective semiconductor substrates 20 and 30 in advance and the activation treatment is performed, following which the pad electrodes are bonded to each other to thereby couple the first substrate 100, the second substrate 200, and the third substrate 300 together. This makes it possible to prevent degradation in the characteristics of the sensor pixels 11 formed in the first substrate 100 and the transistors formed in the lower substrates (e.g., the transfer transistor TR, the amplification transistor AMP, and the like in the present embodiment).

Moreover, in the present embodiment, the first substrate 100 and the second substrate 200 are coupled to each other by bonding the pad electrode 44 and the pad electrode 54 to each other, and the second substrate 200 and the third substrate 300 are coupled to each other by bonding the pad electrode 55 and the pad electrode 64 to each other. This allows for simpler electrical coupling between the substrates as compared with a case of electrically coupling the respective substrates to each other with use of coupling wiring lines such as through wiring lines. In addition, flexibility of the layout increases because there is no need for a formation region for the coupling wiring lines.

In the following, second to seventh embodiments and Modification Examples 1 to 5 are described. It is to be noted that in the following description, the same components as those of the first embodiment described above are denoted by the same reference signs, and description thereof will be omitted as appropriate.

### 2. Second Embodiment

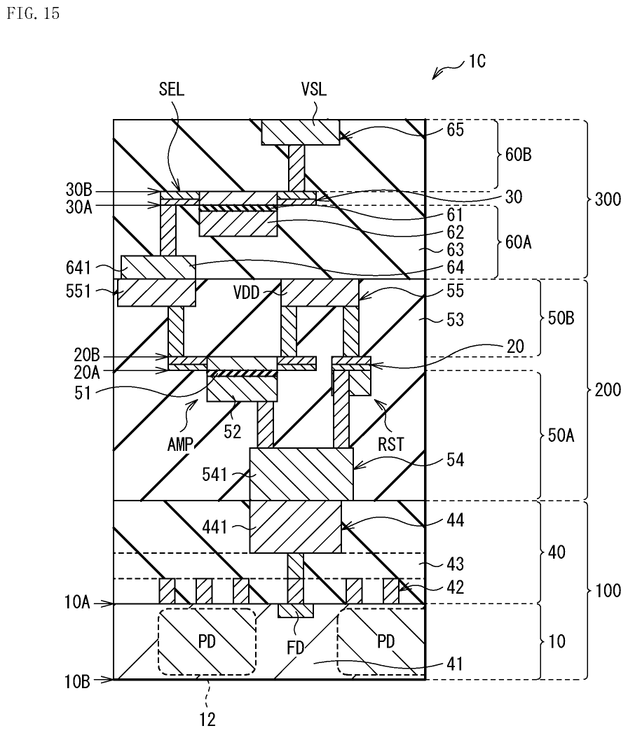

FIG. 11 schematically illustrates an example of a cross-sectional configuration of an imaging device (imaging device 1A) of a second embodiment of the present disclosure. FIG. 12 illustrates an example of an equivalent circuit of the imaging device 1A illustrated in FIG. 11. The imaging device 1A of the present embodiment is different from the first embodiment described above in that the amplification transistor AMP, for example, of the amplification transistor AMP, the reset transistor RST, and the selection transistor SEL that configure the pixel circuit, is provided on the semiconductor substrate 20 of the second substrate 200, and the reset transistor RST and the selection transistor SEL are each provided on the semiconductor substrate 30 of the third substrate 300.

In general, from the viewpoint of parasitic capacitance, the amplification transistor AMP is preferably at a smaller distance from the floating diffusion FD. In addition, also from the viewpoint of noise, the amplification transistor AMP is preferably higher in the ratio (W/L) of the channel width (W) to the channel length (L) of the transistor than the reset transistor RST and the selection transistor SEL.

To cope with this, in the present embodiment, only the amplification transistor AMP is provided on the semiconductor substrate 20 of the second substrate 200, and the reset transistor RST and the selection transistor SEL are provided on the semiconductor substrate 30 of the third substrate 300. An effect is thus achieved that it is possible to sufficiently secure the formation area of the amplification transistor AMP, in addition to the effects of the first embodiment described above.

### 3. Third Embodiment

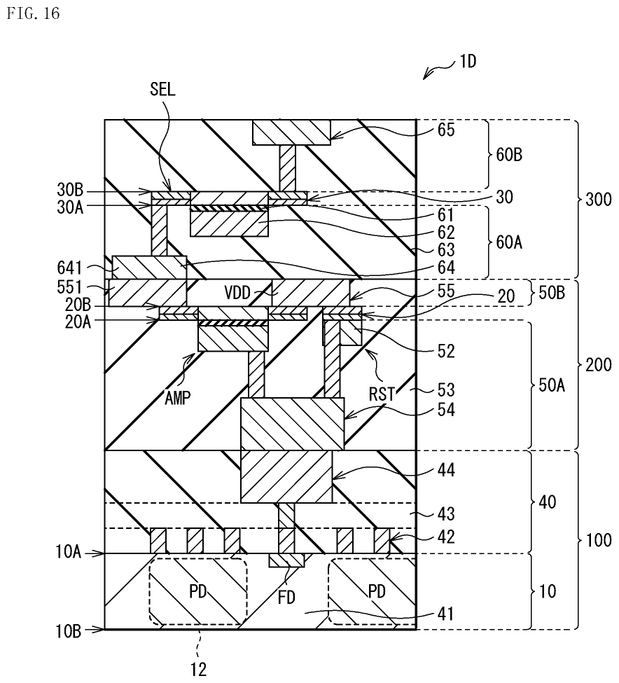

FIG. 13 schematically illustrates an example of a cross-sectional configuration of an imaging device (imaging device 1B) of a third embodiment of the present disclosure. FIG. 14 illustrates an example of an equivalent circuit of the imaging device 1B illustrated in FIG. 13. The imaging device 1B according to the present embodiment is different from the first and second embodiments described above in that the amplification transistor AMP, the reset transistor RST, and the selection transistor SEL that configure the pixel circuit are provided separately in the second substrate 200, the third substrate 300, and a fourth substrate 400, respectively.

In this way, in the present embodiment, the amplification transistor AMP is provided on the semiconductor substrate 20 of the second substrate 200, the reset transistor RST is provided on the semiconductor substrate 30 of the third substrate 300, and the selection transistor SEL is provided on a semiconductor substrate 70 of the fourth substrate 400. An effect is thus achieved that it is possible to sufficiently secure the respective formation areas of the amplification transistor AMP, the reset transistor RST, and the selection transistor, in addition to the effects of the first embodiment described above. In addition, it is possible to further reduce the pixel size.

### 4. Fourth Embodiment

FIG. 15 schematically illustrates an example of a cross-sectional configuration of an imaging device (imaging device 1C) according to a fourth embodiment of the present disclosure. The imaging device 1C of the present embodiment is different from the first to third embodiments described above in that a metal material, instead of polysilicon (Poly-Si), is used for the gate wiring lines TRG1, TRG2, TRG3, and TRG4 of the transfer transistors TR and the respective gate electrodes 52G and 62G of the amplification transistors AMP, the reset transistors RST, and the selection transistors SEL.

Examples of the metal material configuring the gate wiring lines TRG1, TRG2, TRG3, and TRG4 of the transfer transistors TR and the respective gate electrodes 52G and 62G of the amplification transistors AMP, the reset transistors RST, and the selection transistors SEL include metals having a high work function (WF), including, for example, titanium (Ti), tantalum (Ta), titanium nitride (TiN), and tantalum nitride (TaN). Other than these examples, tungsten (W), aluminum (Al), and the like are also usable.

It is to be noted that in a case where the metal material is used to form the gate electrodes 52G and 62G as described above, it is preferable to use a high dielectric material (High-K material) such as hafnium oxide (HfO₂) for each of the gate insulating films 51 and 61.

In this way, in the present embodiment, the metal material is used to form the gate wiring lines TRG1, TRG2, TRG3, and TRG4 of the transfer transistors TR and the respective gate electrodes 52G and 62G of the amplification transistors AMP, the reset transistors RST, and the selection transistors SEL. An effect is thus achieved that it is possible to reduce an influence of an IR drop on each of the transistors TR, AMP, RST, and SEL, in addition to the effects of the first embodiment described above.

In addition, in the present embodiment, because the metal material is used to form the gate wiring lines TRG1, TRG2, TRG3, and TRG4 of the transfer transistors TR, it is possible to route the gate wiring lines TRG1, TRG2, TRG3, and TRG4 as they are, as illustrated in FIG. 15. Accordingly, it is possible to reduce the total number of wiring lines in the wiring layer 40 of the first substrate 100. This makes it possible to reduce the parasitic capacitance with respect to the amplification transistor AMP. In addition, it is possible to reduce the number of steps of the manufacturing process.

### 5. Fifth Embodiment

FIG. 16 schematically illustrates an example of a cross-sectional configuration of an imaging device (imaging device 1D) according to a fifth embodiment of the present disclosure. The imaging device 1D of the present embodiment is different from the first to fourth embodiments described above in that the electrical coupling between the source region 21S of the amplification transistor AMP and the pad electrode 55 (the pad electrode 551) and the electrical coupling between the drain region 21D of each of the amplification transistor AMP and the reset transistor RST and the power supply line VDD in the upper wiring layer 50B of the second substrate 200 are each achieved by direct coupling without the intervention of any vias.

In this way, in the present embodiment, the source region 21S of the amplification transistor AMP and the pad electrode 551 are directly coupled to each other, and the drain region 21D of each of the amplification transistor AMP and the reset transistor RST and the power supply line VDD are directly coupled to each other. An effect is thus achieved that it is possible to reduce the number of steps of the manufacturing process, in addition to the effects of the first embodiment described above.

### 6. Sixth Embodiment

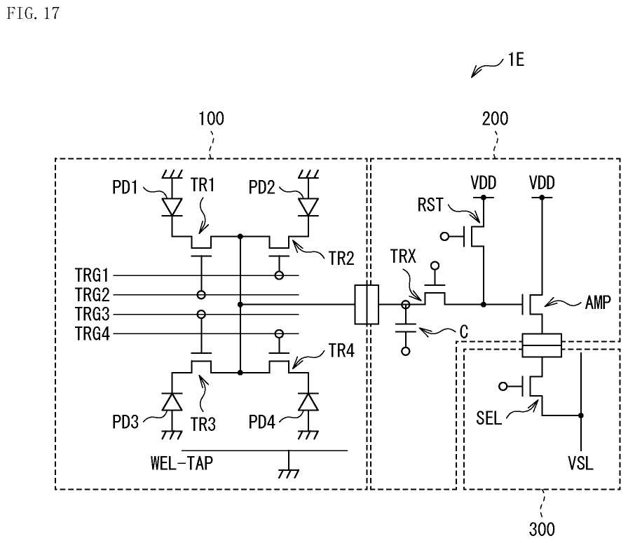

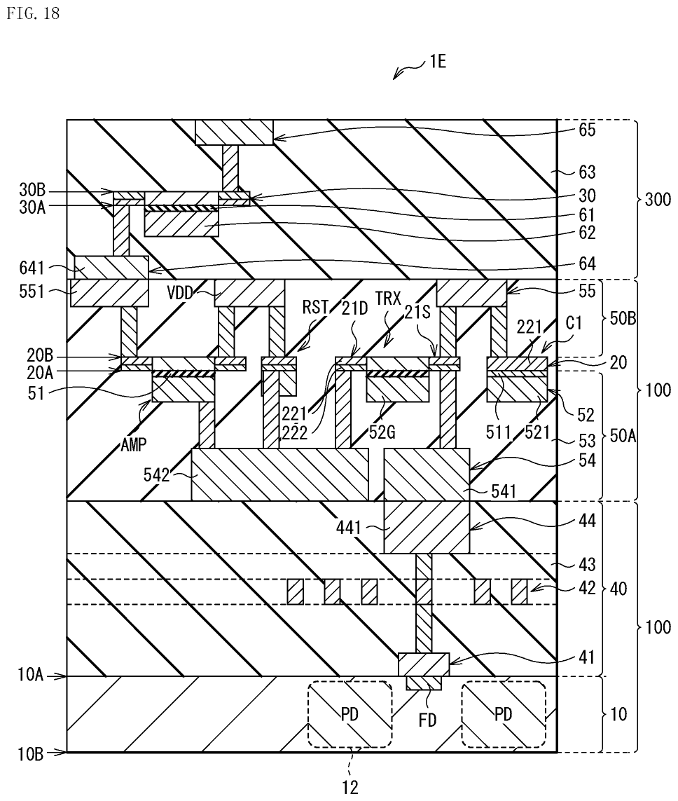

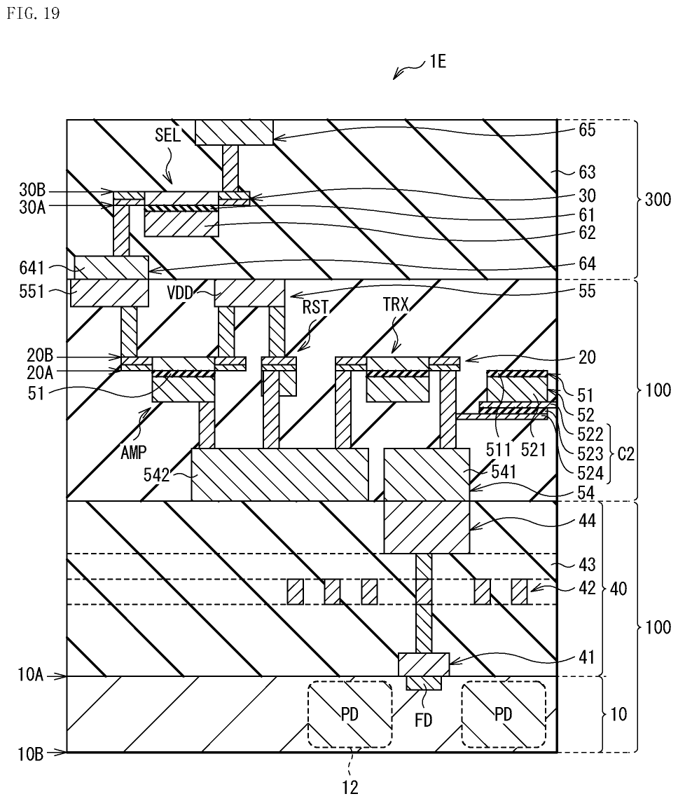

FIG. 17 schematically illustrates an example of an equivalent circuit of an imaging device (imaging device 1E) according to a sixth embodiment of the present disclosure. FIG. 18 schematically illustrates an example of a cross-sectional configuration of the imaging device 1E illustrated in FIG. 17. The imaging device 1E of the present embodiment is different from the first to fifth embodiments described above in that a capacitor C and a switching transistor TRX are provided between the floating diffusion FD and the amplification transistor AMP.

In the present embodiment, the capacitor C and the switching transistor TRX are each provided in the second substrate 200 together with the amplification transistor AMP and the reset transistor RST.

The capacitor C has a structure in which, for example, the diffusion layer 211, an insulating film 511, and an electrically-conductive film 521 are stacked in this order on the semiconductor substrate 20. The diffusion layer 211 is formed by diffusing impurities therein. The insulating film 511 has a configuration similar to that of the gate insulating film 51 of the amplification transistor AMP or the like. The electrically-conductive film 521 includes polysilicon (Poly-Si), for example, similarly to the gate electrode 52G of the amplification transistor AMP or the like.

The switching transistor TRX is intended to switch between coupling and decoupling between the pixel circuit and the capacitor C. The switching transistor TRX has a configuration similar to that of the amplification transistor AMP or the like, for example. Specifically, the switching transistor TRX has a planar structure, and includes the gate electrode 52G, the source region 21S, and the drain region 21D. The gate electrode 52G is provided on the first surface 20A side of the semiconductor substrate 20 with the gate insulating film 51 interposed between the gate electrode 52G and the first surface 20A. The gate insulating film 51 includes, for example, silicon oxide (SiO₂) or the like. The gate electrode 52G includes polysilicon (Poly-Si), for example. The source region 21S and the drain region 21D are provided across a channel region opposed to the gate electrode 52G from each other, and each have a stacked structure of, for example, the diffusion layer 211 including impurities diffused therein and the low-resistance layer 212 including a silicide formed with use of a Salicide process, such as cobalt silicide (CoSi2) or nickel silicide (NiSi), for example.

The capacitor C and the switching transistor TRX are electrically coupled to each other, for example, in the upper wiring layer 50B, through one pad electrode 55 (a pad electrode 552) exposed at the surface facing the third substrate 300 and respective vias provided between the pad electrode 552 and the capacitor C and between the pad electrode 552 and the source region 21S of the switching transistor TRX. The source region 21S of the switching transistor TRX is further electrically coupled through a via, in the lower wiring layer 50A, to the one pad electrode 541 that is exposed at the surface facing the first substrate 100 and that is to be bonded to the pad electrode 441 on the first substrate 100 side. The drain region 21D of the switching transistor TRX is electrically coupled, through a via, to one pad electrode 54 (a pad electrode 542) that is not to be used for bonding to the first substrate 100. The gate electrode 52G of the amplification transistor AMP and the source region 21S of the reset transistor RST are electrically coupled to the pad electrode 542 through respective vias. That is, the drain region 21D of the switching transistor TRX is electrically coupled to each of the gate electrode 51G of the amplification transistor AMP and the source region 21S of the reset transistor RST.

As has been described, in the present embodiment, the capacitor C and the switching transistor TRX are provided between the floating diffusion FD and the amplification transistor AMP. This allows the capacitance of the floating diffusion FD to be variable. Accordingly, it is possible to achieve a so-called global shutter function, in addition to the effects of the first embodiment described above.

In this way, the imaging device 1 and the like of the present disclosure make it possible to add the capacitor C and the switching transistor TRX because the amplification transistor AMP, the reset transistor RST, and the selection transistor SEL that configure the pixel circuit are formed separately in multiple substrates.

It is to be noted that the present embodiment describes an example in which the capacitor C is used for achieving the global shutter function; however, in addition to this, the capacitor C is also usable for capacitance addition or the like to prevent a signal swing or the like of a circuit.

### 7. Modification Examples

The sixth embodiment described above describes an example in which, as the capacitor C, the diffusion layer 211 including impurities diffused therein, the insulating film 511 including, for example, silicon oxide (SiO₂) or the like, and the electrically-conductive film 521 including, for example, polysilicon (Poly-Si) are stacked in this order on the semiconductor substrate 20; however, the capacitor C may have a different configuration.

### 7-1. Modification Example 1

FIG. 19 schematically illustrates an example of a cross-sectional configuration of an imaging device 1E according to Modification Example 1 of the present disclosure. The imaging device 1E of the present modification example is different from the sixth embodiment described above in that a capacitor C1 having a metal-insulator-metal stacked structure is provided as the capacitor C.

The capacitor C1 has a so-called MIM structure in which, for example, a metal film 522, an insulating film 523, and a metal film 524 are stacked in this order on the electrically-conductive film 521, of the insulating film 511 and the electrically-conductive film 521 that are stacked in this order on the first surface 20A side of the semiconductor substrate 20. It is possible to form each of the metal films 522 and 524 with use of titanium nitride (TiN), for example. It is possible to form the insulating film 523 with use of a high dielectric material (High-K material), for example. The metal film 524 extends in a planar direction, for example, and is electrically coupled to the via that electrically couples the source region 21S of the switching transistor TRX and the pad electrode 44 to each other.

In this way, the capacitor C (the capacitor C1) may have a MIM structure and may be electrically coupled to the source region 21S of the switching transistor TRX within the lower wiring layer 50A, for example. This makes it possible to form the capacitor C1 in advance of the step of bonding to the first substrate 100.

### 7-2. Modification Example 2

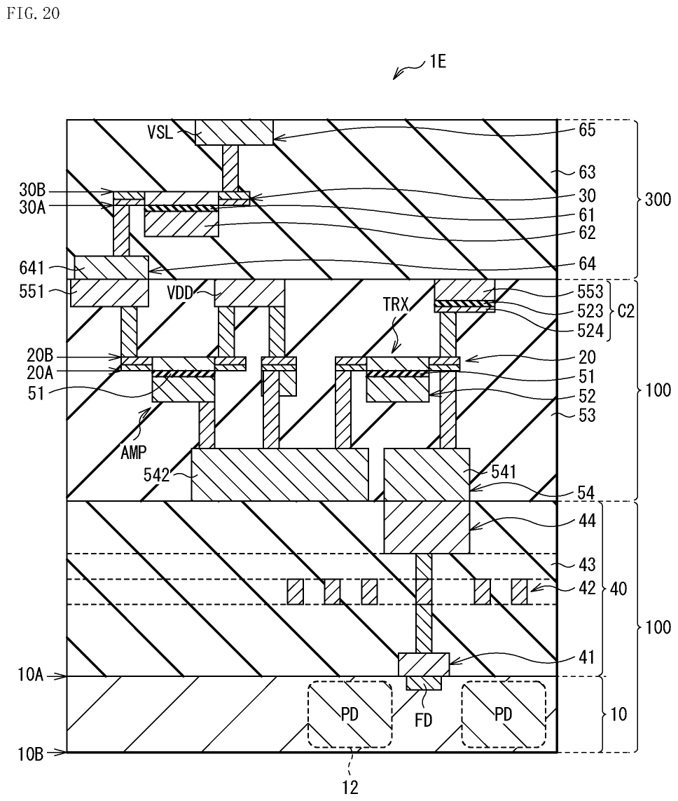

FIG. 20 schematically illustrates an example of a cross-sectional configuration of an imaging device 1E according to Modification Example 2 of the present disclosure. The imaging device 1E of the present modification example is different from Modification Example 1 described above in that a capacitor C2 having a metal-insulator-metal stacked structure is provided to be exposed at the surface of the upper wiring layer 50B facing the third substrate 300.

Similarly to the capacitor C1, the capacitor C2 has the so-called MIM structure. In the present modification example, the capacitor C2 has a configuration in which one pad electrode 55 (a pad electrode 553) exposed at the surface facing the third substrate 300, the insulating film 523, and the metal film 524 are stacked. The metal film 524 is electrically coupled to the source region 21S of the switching transistor TRX through a via, for example.

In this way, the capacitor C (the capacitor C2) may have the MIM structure, and one of the multiple pad electrodes 54 (the pad electrode 553) exposed at the interlayer insulating layer 53 of the upper wiring layer 50B, for example, may be used as a metal film of the capacitor C2. This makes it possible to achieve easy manufacture, as compared with the capacitor C of Modification Example 1 described above.

### 7-3. Modification Example 3

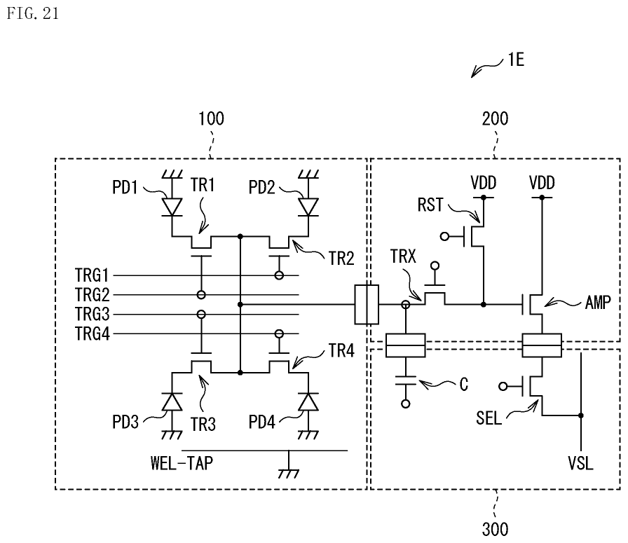

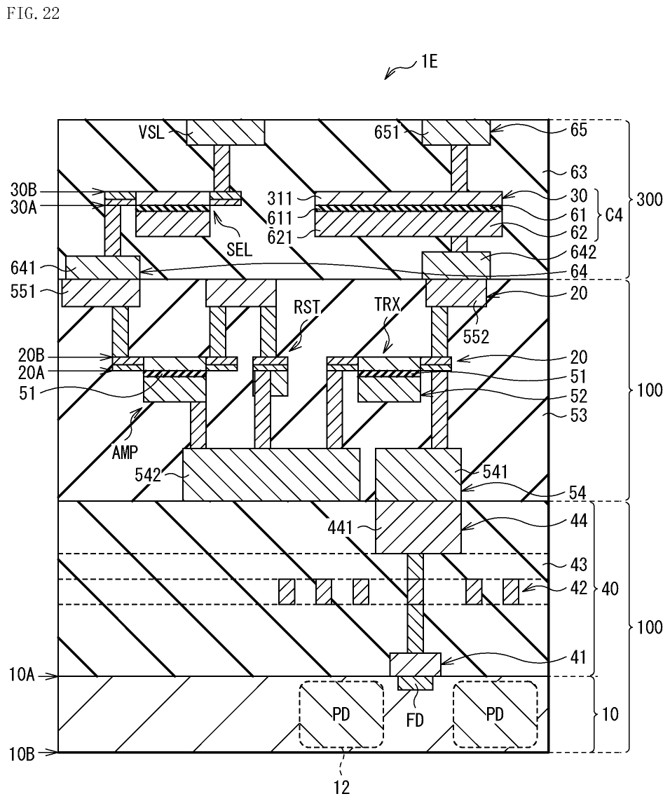

FIG. 21 schematically illustrates an example of an equivalent circuit of an imaging device 1E according to Modification Example 3 of the present disclosure. FIG. 22 schematically illustrates an example of a cross-sectional configuration of the imaging device 1E illustrated in FIG. 21. The imaging device 1E of the present modification example is different from the sixth embodiment and Modification Examples 1 and 2 described above in that a capacitor C3 is provided in the third substrate 300.

Similarly to the capacitor C in the sixth embodiment described above, for example, the capacitor C3 has a structure in which a diffusion layer 311 formed by diffusing impurities in the semiconductor substrate 30, an insulating film 611 having a configuration similar to that of the gate insulating film 61 of the selection transistor SEL or the like, and an electrically-conductive film 621 including, for example, polysilicon (Poly-Si) similarly to the gate electrode 62G of the selection transistor SEL are stacked in this order. In the present modification example, the diffusion layer 311 is electrically coupled, through a via, to one pad electrode 65 (a pad electrode 651) exposed at a surface of the interlayer insulating layer 63 opposite to the second substrate 200 side. In addition, the electrically-conductive film 621 is electrically coupled to the source region 20S of the switching transistor TRX through one pad electrode 64 (a pad electrode 642) exposed at the surface of the interlayer insulating layer 63 facing the second substrate 200, a via provided between the electrically-conductive film 621 and the pad electrode 642, one pad electrode 552 exposed at the surface of the upper wiring layer 50B of the second substrate 200 facing the third substrate 300, and a via provided between the pad electrode 552 and the source region 20S of the switching transistor TRX.

In this way, the capacitor C (the capacitor C3) may be provided in the third substrate 300. This makes it possible to increase the capacitance of the capacitor C3 without consuming the formation region of each of the transistors configuring the pixel circuit.

### 7-4. Modification Example 4

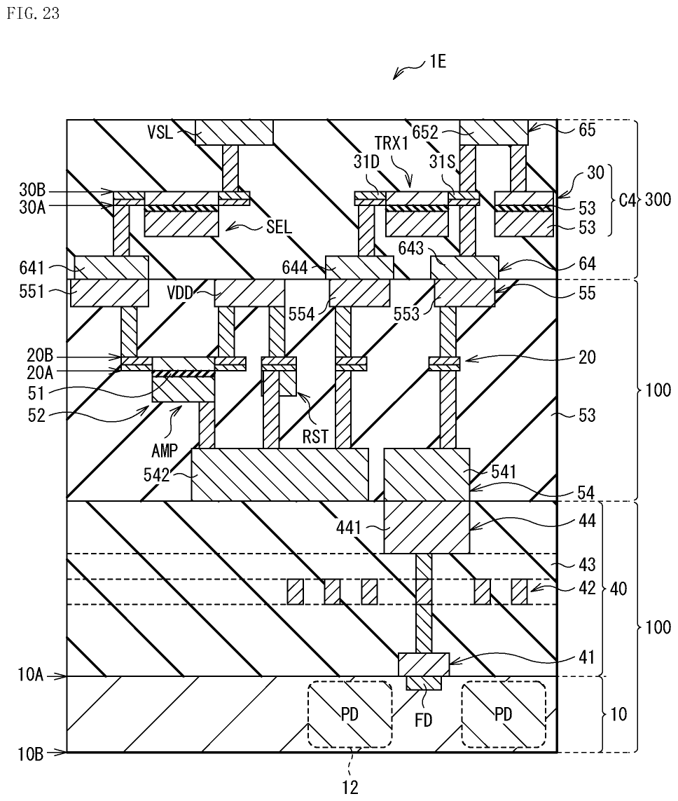

FIG. 23 schematically illustrates an example of a cross-sectional configuration of an imaging device 1E according to Modification Example 4 of the present disclosure. The imaging device 1E of the present modification example is different from Modification Example 3 described above in that the switching transistor TRX (a switching transistor TRX1) is provided in the third substrate 300 together with the capacitor C3.

The switching transistor TRX1 of the present modification example has a configuration similar to that of the switching transistor TRX of the sixth embodiment described above. Specifically, the switching transistor TRX1 has a planar structure, for example, and includes the gate electrode 62G, the source region 31S, and the drain region 31D, similarly to the selection transistor SEL.

The capacitor C3 and the switching transistor TRX1 are electrically coupled to each other, for example, in the upper wiring layer 60B, through one pad electrode 652 and respective vias provided between the pad electrode 652 and the capacitor C3 and between the pad electrode 652 and the source region 31S of the switching transistor TRX1. The source region 31S of the switching transistor TRX1 is further electrically coupled through a via, in the lower wiring layer 60A, to a pad electrode 643 exposed at the surface facing the second substrate 200. The drain region 31D of the switching transistor TRX1 is electrically coupled, through a via, to a pad electrode 644 exposed at the surface facing the second substrate 200. The pad electrode 643 and the pad electrode 644 are respectively electrically coupled, in the lower wiring layer 50A of the second substrate 200, to the pad electrode 541 and the pad electrode 542 exposed at the surface facing the first substrate, through a via and a stacked film of the diffusion layer 211 and the low-resistance layer 212. Thus, the source region 31S of the switching transistor TRX1 is electrically coupled to the floating diffusion FD, and the drain region 31D of the switching transistor TRX1 is electrically coupled to each of the gate electrode 51G of the amplification transistor AMP and the source region 21S of the reset transistor RST.

In this way, the switching transistor TRX (the switching transistor TRX1) may be provided in the third substrate 300.

### 7-5. Modification Example 5

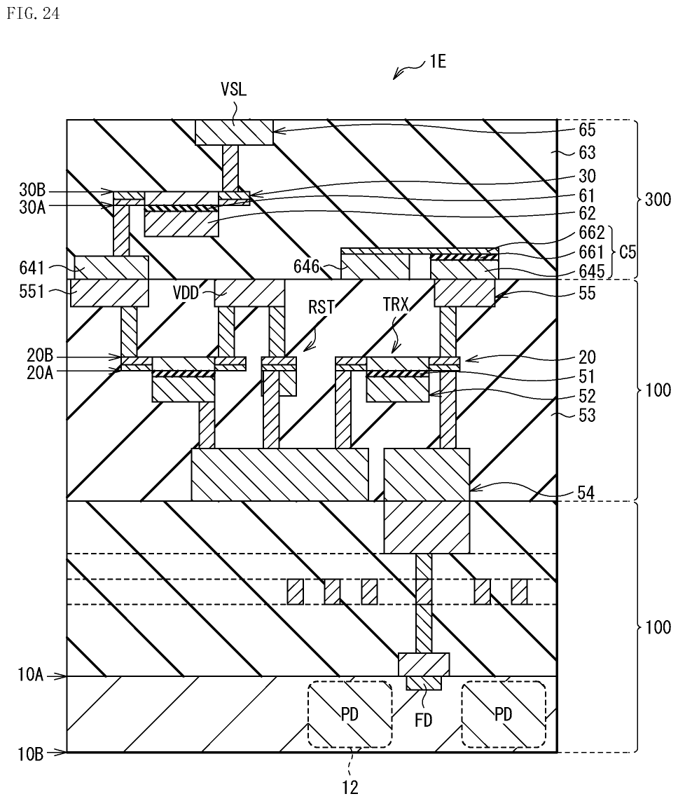

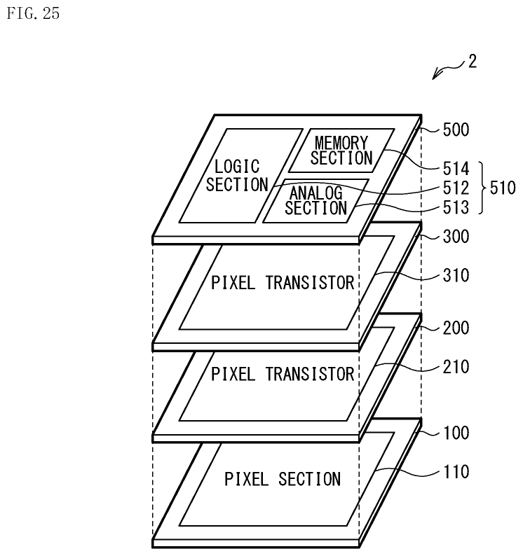

FIG. 24 schematically illustrates an example of a cross-sectional configuration of an imaging device 1E according to Modification Example 5 of the present disclosure. The imaging device 1E of the present modification example is different from Modification Example 2 described above in that a capacitor C5 having the MIM structure, for example, is provided to be exposed at the surface of the lower wiring layer 60A of the third substrate 300 facing the second substrate 200.

The capacitor C5 has a configuration similar to that of the capacitor C2. Specifically, the capacitor C5 has a configuration in which one pad electrode 645 provided to be exposed at the surface facing the second substrate 200, an insulating film 661, and a metal film 662 are stacked. The pad electrode 645 is electrically coupled to the source region 21S of the switching transistor TRX through the pad electrode 551 of the second substrate 200 and a via. The metal film 662 extends in the planar direction, for example, and is electrically coupled to one pad electrode 646 provided to be exposed at the surface facing the second substrate 200, similarly to the pad electrode 645, for example.

In this way, the capacitor C (the capacitor C5) may use one of the multiple pad electrodes 64 (the pad electrode 645) provided to be exposed at the surface of the interlayer insulating layer 63 of the lower wiring layer 60A, for example, as a metal film of the capacitor C2.

It is to be noted that the sixth embodiment and Modification Examples 1 to 5 described above may be combined as appropriate. For example, although Modification Examples 3 and 4 describe the capacitors C3 and C4 including the diffusion layer 311, the insulating film 611, and the electrically-conductive film 621, the capacitors C3 and C4 may have the MIM structure similarly to the capacitors C1 and C2 described in Modification Examples 1 and 2, for example.

In addition, although the sixth embodiment and Modification Examples 1 to 5 described above describe an example in which the capacitor C and the switching transistor TRX are further provided, a resistor or the like may further be provided.

### 8. Seventh Embodiment

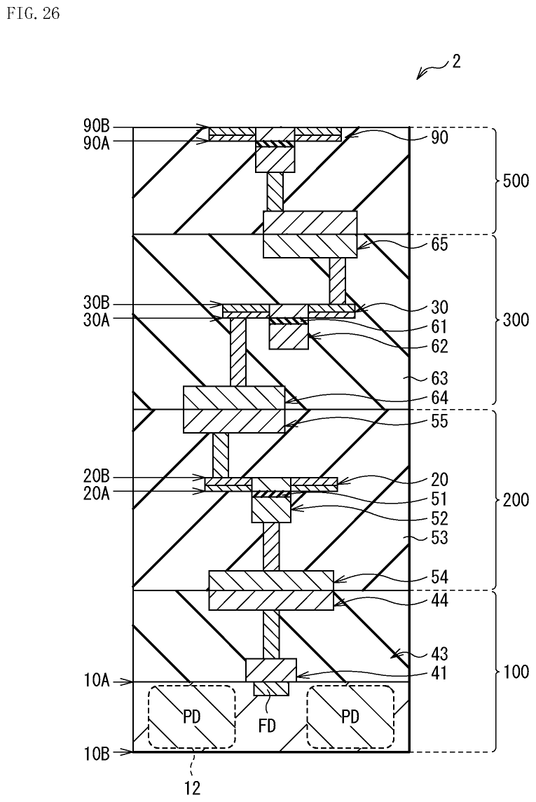

FIG. 25 is an exploded perspective diagram illustrating a schematic configuration of an imaging device (imaging device 2) according to a seventh embodiment of the present disclosure. FIG. 26 schematically illustrates an example of a cross-sectional configuration of the imaging device 2 illustrated in FIG. 25. The imaging device 2 according to the present embodiment is different from the first to sixth embodiments and Modification Examples 1 to 5 described above in that a fifth substrate 500 provided with a logic circuit 510 is further stacked on the third substrate 300 in the stack including the first substrate 100, the second substrate 200, and the third substrate 300 that are stacked in this order. The first substrate 100 includes a pixel section 110 in which multiple sensor pixels 11 are arranged in an array. The second substrate 200 is provided with the amplification transistor AMP and the reset transistor RST (pixel transistors 210) configuring the pixel circuit. The third substrate 300 is provided with the selection transistor SEL (a pixel transistor 310) configuring the pixel circuit.

In the fifth substrate 500, for example, as described above, the logic circuit 510 is formed on a semiconductor substrate 90 having a first surface 90A and a second surface 90B opposed to each other. The logic circuit 510 controls the pixel section 110 and the amplification transistor AMP, the reset transistor RST, and the selection transistor SEL that configure the pixel transistors 210 and 310, and processes the pixel signal obtained from each pixel circuit. The logic circuit 510 includes, for example, a logic section 512 (SC, IO, CPU, IF), an analog section 513 (ADC, CM, DAC), and a memory section 514 (a static RAM (SRAM), a dynamic RAM (DRAM), a magnetoresistive memory (MRAM), a resistance change memory (ReRAM), a ferroelectric memory (FeRAM), a phase change memory (PCRAM), or a flash memory), etc.

As has been described, in the imaging device 2 of the present embodiment, the logic circuit 510 is further provided in the fifth substrate 500, and the fifth substrate 500 is stacked on the third substrate 300. An effect is thus achieved that it is possible to make the imaging device 1 smaller in size, in addition to the effects of the first embodiment described above.

In addition, although the present embodiment describes an example in which the amplification transistor AMP, the reset transistor RST, and the selection transistor SEL that configure the pixel circuit are formed separately in two substrates, i.e., the second substrate 200 and the third substrate 300, and the fifth substrate 500 is stacked on the third substrate 300, this is not limitative. For example, the amplification transistor AMP, the reset transistor RST, and the selection transistor SEL may be formed separately in three substrates, i.e., the second substrate 200, the third substrate 300, and the fourth substrate 400 as in the imaging device 1B of the third embodiment described above, and the fifth substrate 500 may be stacked on the fourth substrate.

Furthermore, although the present embodiment describes an example in which the logic circuit 510 is provided in one substrate (the fifth substrate 500), the logic circuits 510 may be provided separately in multiple substrates similarly to the pixel circuits of the present disclosure, and the multiple substrates may be stacked on the third substrate 300, for example.

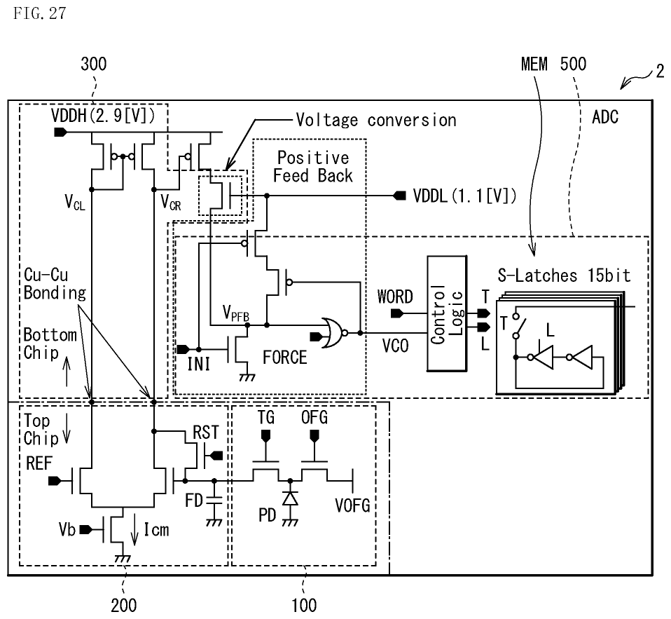

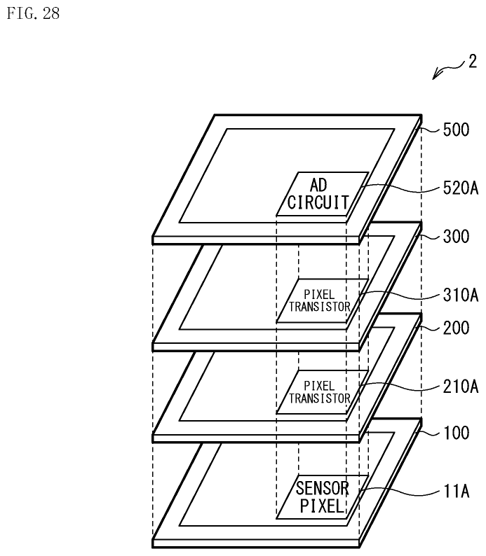

Still furthermore, as illustrated in FIG. 27, for example, an ADC circuit including a memory (MEM) may be provided in a pixel circuit that is provided for each sensor pixel 11 or for each pixel-sharing unit, and this structure may be formed in the fifth substrate 500. The ADC circuit portion including the MEM is mountable for each sensor pixel 11 because the formation area thereof is reducible by applying the latest core. In addition, forming the MEM portion of the ADC circuit with use of the MRAM, the ReRAM, the FeRAM, the PCRAM, the flash memory or the like described above makes it possible, as illustrated in FIG. 28, for example, to form one sensor pixel 11A provided in the first substrate 100, pixel transistors 210A and 310A corresponding to the one sensor pixel 11A and provided respectively in the second substrate 200 and the third substrate 300, and an ADC circuit 520A provided in the fifth substrate 500 to have areas substantially equal to each other.

### 9. Application Example

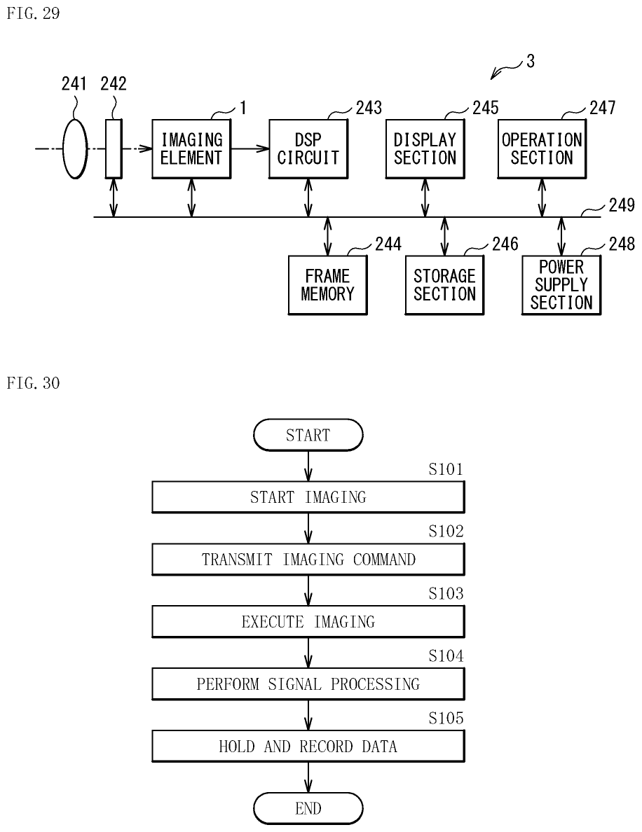

FIG. 29 illustrates an example of a schematic configuration of an imaging system 3 that includes the imaging device according to any of the first to seventh embodiments and Modification Examples 1 to 5 described above (for example, the imaging device 1).

The imaging system 3 is an electronic apparatus which is, for example, an imaging device such as a digital still camera or a video camera, a portable terminal device such as a smartphone or a tablet-type terminal, or the like. The imaging system 3 includes, for example, the imaging device 1 according to any of the embodiments described above and the modification examples thereof, an optical system 241, a shutter device 242, a DSP circuit 243, a frame memory 244, a display section 245, a storage section 246, an operation section 247, and a power supply section 248. In the imaging system 3, the imaging device 1 according to any of the embodiments described above and the modification examples thereof, the DSP circuit 243, the frame memory 244, the display section 245, the storage section 246, the operation section 247, and the power supply section 248 are coupled to each other through a bus line 249.

The imaging device 1 according to any of the embodiments described above and the modification examples thereof outputs image data corresponding to entering light. The optical system 241 includes one or multiple lenses. The optical system 241 guides light (entering light) from a subject to the imaging device 1 to form an image on a light-receiving surface of the imaging device 1. The shutter device 242 is disposed between the optical system 241 and the imaging device 1. The shutter device 242 controls a period of applying light to the imaging device 1 and a period of blocking the light in accordance with control by a drive circuit. The DSP circuit 243 is a signal processing circuit that processes a signal (image data) outputted from the imaging device 1 according to any of the embodiments described above and the modification examples thereof. The frame memory 244 temporarily holds the image data processed by the DSP circuit 243 in a frame unit. The display section 245 includes, for example, a panel-type display device such as a liquid crystal panel or an organic EL (Electro Luminescence) panel and displays a moving image or a still image captured by the imaging device 1 according to any of the embodiments described above and the modification examples thereof. The storage section 246 records image data of a moving image or a still image captured by the imaging device 1 according to any of the embodiments described above and the modification examples thereof in a recording medium such as a semiconductor memory or a hard disk. The operation section 247 issues an operation instruction for various functions of the imaging system 3 in accordance with an operation by a user. The power supply section 248 appropriately supplies various kinds of power for operation to the imaging device 1 according to any of the embodiments described above and the modification examples thereof, the DSP circuit 243, the frame memory 244, the display section 245, the storage section 246, and the operation section 247 that are supply targets.

Next, an imaging procedure in the imaging system 3 is described.

FIG. 30 illustrates an example of a flowchart of an imaging operation in the imaging system 3. A user issues an instruction to start imaging by operating the operation section 247 (step S101). The operation section 247 then transmits an imaging instruction to the imaging device 1 (step S102). The imaging device 1 (specifically, a system control circuit) executes imaging in a predetermined imaging scheme upon receiving the imaging instruction (step S103).

The imaging device 1 outputs image data obtained through imaging to the DSP circuit 243. Here, the image data refers to data for all of the pixels of pixel signals generated on the basis of electric charge temporarily held by the floating diffusion FD. The DSP circuit 243 performs predetermined signal processing (e.g., noise reduction processing or the like) on the basis of the image data inputted from the imaging device 1 (step S104). The DSP circuit 243 causes the frame memory 244 to hold the image data that has undergone the predetermined signal processing, and the frame memory 244 stores the image data in the storage section 246 (step S105). In this manner, imaging is performed by the imaging system 3.

In the present application example, the imaging device 1 according to any of the embodiments described above and the modification examples thereof is applied to the imaging system 3. This allows the imaging device 1 to be smaller in size or higher in definition. This makes it possible to provide the small-sized or high-definition imaging system 3.

### 10. Practical Application Examples

### (Example of Practical Application to Mobile Body)

The technology (the present technology) according to the present disclosure is applicable to a variety of products. For example, the technology according to the present disclosure may be implemented as a device mountable on any type of mobile body such as an automobile, an electric vehicle, a hybrid electric vehicle, a motorcycle, a bicycle, a personal mobility, an airplane, a drone, a vessel, or a robot.

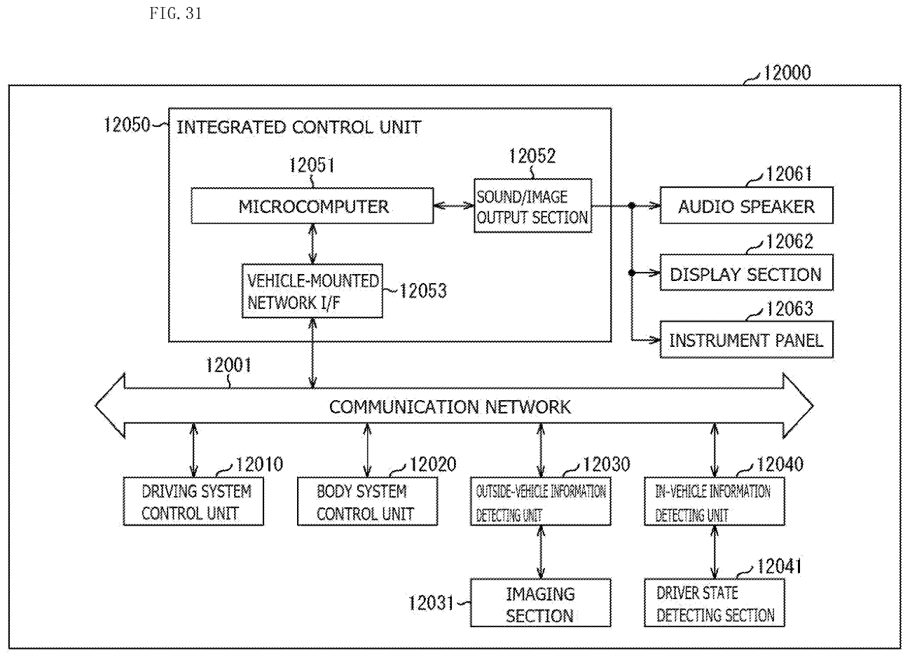

FIG. 31 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 31, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

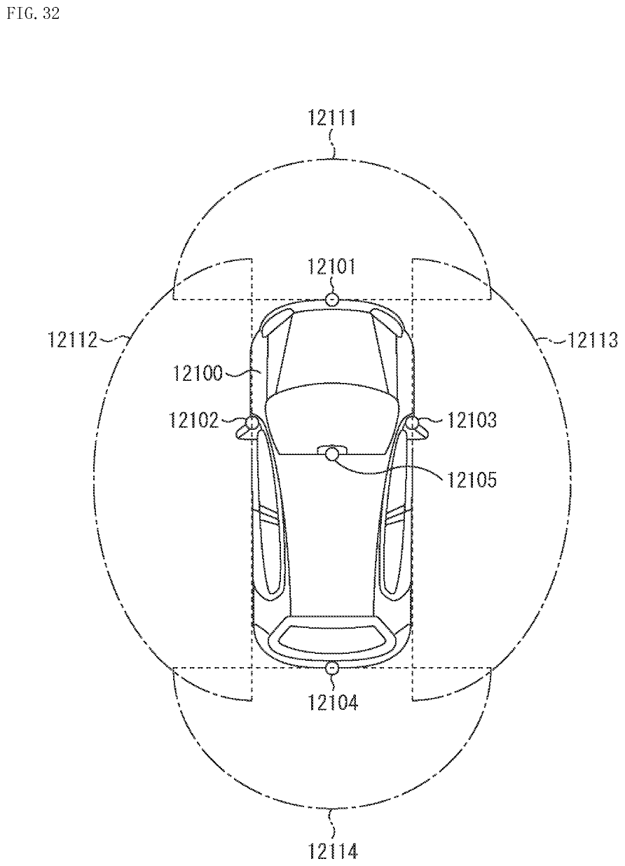

FIG. 32 is a diagram depicting an example of the installation position of the imaging section 12031.

In FIG. 32, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 32 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to the present disclosure may be applied. The technology according to the present disclosure may be applied to the imaging section 12031 among the components described above. Specifically, the imaging device 1 according to any of the embodiments described above and the modification examples thereof is applicable to the imaging section 12031. The application of the technology according to the present disclosure to the imaging section 12031 makes it possible to obtain a high-definition shot image with less noise and it is thus possible to perform highly accurate control using the shot image in the mobile body control system.

### (Example of Practical Application to Endoscopic Surgery System)

The technology according to the present disclosure (the present technology) is applicable to a variety of products. For example, the technology according to the present disclosure may be applied to an endoscopic surgery system.

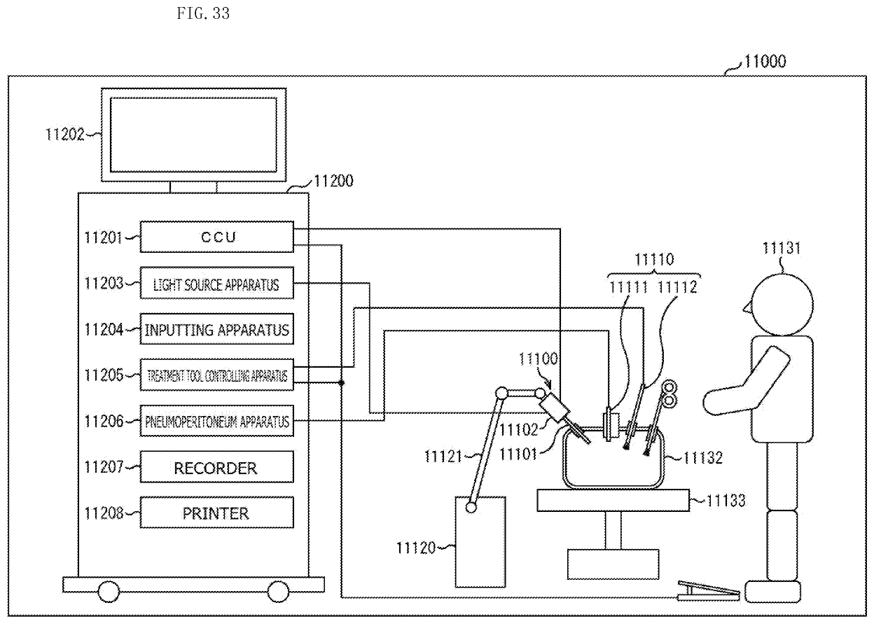

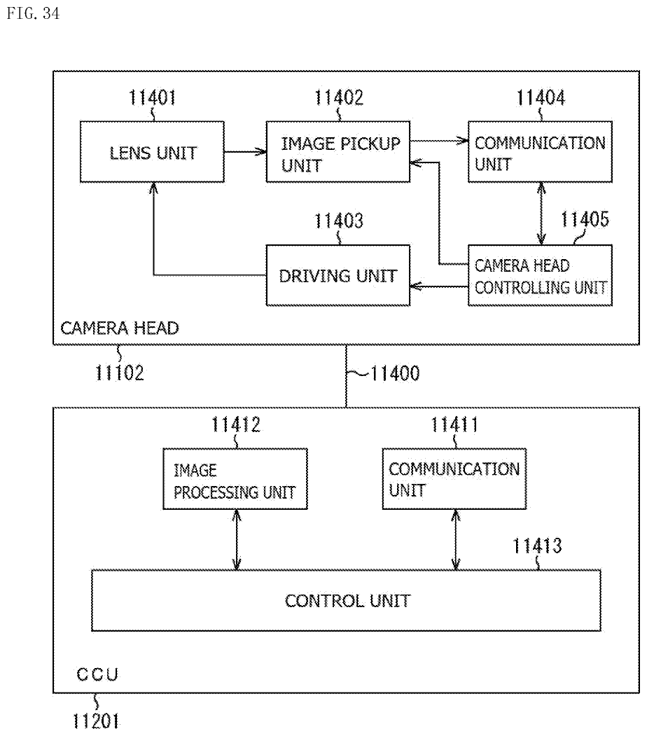

FIG. 33 is a view depicting an example of a schematic configuration of an endoscopic surgery system to which the technology according to an embodiment of the present disclosure (present technology) can be applied.

In FIG. 33, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 34 is a block diagram depicting an example of a functional configuration of the camera head 11102 and the CCU 11201 depicted in FIG. 33.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be favorably applied to the image pickup unit 11402 provided to the camera head 11102 of the endoscope 11100 among the components described above. The application of the technology according to the present disclosure to the image pickup unit 11402 allows the image pickup unit 11402 to be smaller in size or higher in definition. This makes it possible to provide the small-sized or high-definition endoscope 11100.

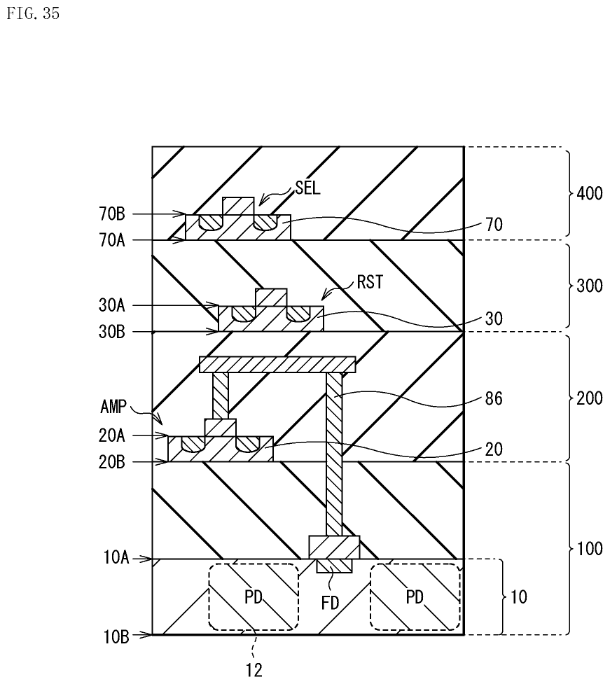

The present disclosure has been described above with reference to the first to seventh embodiments, Modification Examples 1 to 5 thereof, the application example, and the practical application examples; however, the present disclosure is not limited to the embodiments and the like described above, and may be modified in a variety of ways. For example, the embodiments and the like described above describe an example in which the respective substrates (for example, the first substrate 100, the second substrate 200, and the third substrate 300) are electrically coupled by bonding between the pad electrodes; however, this is not limitative. For example, as illustrated in FIG. 35, the first substrate 100 and the second substrate 200 (specifically, the floating diffusion FD provided in the first substrate 100 and the amplification transistor AMP provided in the second substrate 200), for example, may be electrically coupled to each other through a through wiring line 86. In addition, although not illustrated, for example, the first substrate 100 and the third substrate, the first substrate 100 and the fourth substrate, the second substrate 200 and the third substrate 300, the second substrate 200 and the fourth substrate 400, or the third substrate 300 and the fourth substrate 400 are electrically coupled to each other through a through wiring line.

It is to be noted that the effects described herein are mere examples. The effects of the present disclosure are not limited to those described herein. The present disclosure may have effects other than those described herein.

It is to be noted that the present disclosure may also have configurations as follows. According to the present technology having the following configurations, the first transistor and the second transistor configuring the pixel circuit are formed in respective different substrates (the second substrate and the third substrate), and the second substrate and the third substrate are stacked in this order on the first substrate including the sensor pixels performing photoelectric conversion. This reduces the formation area of the pixel circuit in a plan view, making it possible to reduce the pixel size.

(1)

An imaging device including:

a first substrate having a first surface and a second surface and including a sensor pixel on a first semiconductor substrate, the sensor pixel performing photoelectric conversion;

a second substrate having a third surface and a fourth surface and including a first transistor on a second semiconductor substrate, the first transistor configuring a pixel circuit that outputs a pixel signal based on electric charge outputted from the sensor pixel, the second substrate being stacked on the first substrate with the first surface and the third surface being opposed to each other; and

a third substrate having a fifth surface and a sixth surface and including a second transistor on a third semiconductor substrate, the second transistor configuring the pixel circuit, the third substrate being stacked on the second substrate with the fourth surface and the fifth surface being opposed to each other.

(2)

The imaging device according to (1), in which

the first transistor is disposed with a gate surface being opposed to the first surface of the first substrate, and

the second transistor is disposed with a gate surface being opposed to the fourth surface of the second substrate.

(3)

The imaging device according to (1) or (2), in which

the sensor pixel and the first transistor are electrically coupled to each other by bonding between respective pad electrodes formed on the first surface and the third surface, and

the first transistor and the second transistor are electrically coupled to each other by bonding between respective pad electrodes formed on the fourth surface and the fifth surface.

(4)

The imaging device according to (3), in which the pad electrodes include copper as a main material.

(5)

The imaging device according to any one of (1) to (4), in which

the sensor pixel includes a light-receiving element, a transfer transistor electrically coupled to the light-receiving element, and a floating diffusion that temporarily holds electric charge outputted from the light-receiving element through the transfer transistor, and

the pixel circuit includes a reset transistor that resets an electric potential of the floating diffusion to a predetermined position, an amplification transistor that generates, as the pixel signal, a signal of a voltage corresponding to a level of the electric charge held by the floating diffusion, and a selection transistor that controls a timing at which the pixel signal is outputted from the amplification transistor.

(6)

The imaging device according to (5), in which

the amplification transistor and the reset transistor are formed in the second substrate, and

the selection transistor is formed in the third substrate.

(7)

The imaging device according to (5), in which

the amplification transistor is formed in the second substrate, and

the reset transistor and the selection transistor are formed in the third substrate.

(8)

The imaging device according to (5), further including a fourth substrate having a seventh surface and an eighth surface and including a third transistor on a fourth semiconductor substrate, the third transistor configuring the pixel circuit, the fourth substrate being stacked on the third substrate with the sixth surface and the seventh surface being opposed to each other, in which

the amplification transistor is formed in the second substrate,

the reset transistor is formed in the third substrate, and

the selection transistor is formed.

(9)

The imaging device according to any one of (5) to (8), in which a gate electrode of each of the transfer transistor, the reset transistor, the amplification transistor, and the selection transistor includes polysilicon or a metal material.

(10)

The imaging device according to any one of (5) to (9), in which a gate of the transfer transistor includes a metal material, and the gate of the transfer transistor and the floating diffusion are directly coupled to each other.

(11)

The imaging device according to any one of (3) to (10), in which one of a gate electrode, a source region, or a drain region of the first transistor and the pad electrode formed on the fourth surface are directly coupled to each other.

(12)

The imaging device according to any one of (1) to (11), in which the first transistor and the second transistor have a planar structure or a three-dimensional structure.

(13)

The imaging device according to any one of (1) to (12), in which a capacitor is further provided in the second substrate or the third substrate.

(14)

The imaging device according to (13), in which

the sensor pixel includes a light-receiving element, a transfer transistor electrically coupled to the light-receiving element, and a floating diffusion that temporarily holds electric charge outputted from the light-receiving element through the transfer transistor,

the pixel circuit includes a reset transistor that resets an electric potential of the floating diffusion to a predetermined position, an amplification transistor that generates, as the pixel signal, a signal of a voltage corresponding to a level of the electric charge held by the floating diffusion, and a selection transistor that controls a timing at which the pixel signal is outputted from the amplification transistor, and

the capacitor is disposed between the floating diffusion and the amplification transistor.

(15)

The imaging device according to (14), further including a switching transistor that switches between coupling and decoupling of the capacitor.

(16)

The imaging device according to (14) or (15), in which the capacitor has a metal-insulator-metal stacked structure or a metal-oxide-metal stacked structure.

(17)

The imaging device according to any one of (1) to (16), in which a resistor is further provided in the second substrate or the third substrate.

(18)

The imaging device according to any one of (1) to (17), further including a fifth substrate having a ninth surface and a tenth surface and including a logic circuit on a fifth semiconductor substrate, the logic circuit processing the pixel signal, the fifth substrate being stacked over the third substrate with the ninth surface and the sixth surface being opposed to each other.

(19)

The imaging device according to (18), in which the pixel circuit further includes an ADC circuit that converts an analog signal into a digital signal and holds the digital signal, the ADC circuit being provided in the fifth substrate.

(20)

The imaging device according to (19), in which the sensor pixel provided in the first substrate, the first transistor provided in the second substrate, the second transistor provided in the third substrate, and the ADC circuit provided in the fifth substrate have formation areas that are substantially equal to each other.

(21)

The imaging device according to (19) or (20), in which the ADC circuit includes one of a magnetoresistive memory, a resistance change memory, a ferroelectric memory, a phase change memory, or a flash memory.

(22)

The imaging device according to any one of (1) to (21), in which the first substrate and the second substrate, the first substrate and the third substrate, or the second substrate and the third substrate are electrically coupled to each other through a through wiring line that penetrates through one or both of the second semiconductor substrate and the third semiconductor substrate.

(23)

An electronic apparatus including

an imaging device including
a first substrate having a first surface and a second surface and including a sensor pixel on a first semiconductor substrate, the sensor pixel performing photoelectric conversion;
a second substrate having a third surface and a fourth surface and including a first transistor on a second semiconductor substrate, the first transistor configuring a pixel circuit that outputs a pixel signal based on electric charge outputted from the sensor pixel, the second substrate being stacked on the first substrate with the first surface and the third surface being opposed to each other; and
a third substrate having a fifth surface and a sixth surface and including a second transistor on a third semiconductor substrate, the second transistor configuring the pixel circuit, the third substrate being stacked on the second substrate with the fourth surface and the fifth surface being opposed to each other.

The present application claims the benefit of Japanese Priority Patent Application JP2020-064019 filed with the Japan Patent Office on Mar. 31, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging device, comprising:
a first substrate having a first surface and a second surface and including a sensor pixel on a first semiconductor substrate, the sensor pixel performing photoelectric conversion;
a second substrate having a third surface and a fourth surface and including a first transistor on a second semiconductor substrate, the first transistor configuring a pixel circuit that outputs a pixel signal based on electric charge outputted from the sensor pixel, the second substrate being stacked on the first substrate with the first surface and the third surface being opposed to each other; and
a third substrate having a fifth surface and a sixth surface and including a second transistor on a third semiconductor substrate, the second transistor configuring the pixel circuit, the third substrate being stacked on the second substrate with the fourth surface and the fifth surface being opposed to each other.

2. The imaging device according to claim 1, wherein
the first transistor is disposed with a gate surface being opposed to the first surface of the first substrate, and
the second transistor is disposed with a gate surface being opposed to the fourth surface of the second substrate.

3. The imaging device according to claim 1, wherein
the sensor pixel and the first transistor are electrically coupled to each other by bonding between respective pad electrodes formed on the first surface and the third surface, and
the first transistor and the second transistor are electrically coupled to each other by bonding between respective pad electrodes formed on the fourth surface and the fifth surface.

4. The imaging device according to claim 3, wherein the pad electrodes include copper as a main material.

5. The imaging device according to claim 1, wherein
the sensor pixel includes a light-receiving element, a transfer transistor electrically coupled to the light-receiving element, and a floating diffusion that temporarily holds electric charge outputted from the light-receiving element through the transfer transistor, and
the pixel circuit includes a reset transistor that resets an electric potential of the floating diffusion to a predetermined position, an amplification transistor that generates, as the pixel signal, a signal of a voltage corresponding to a level of the electric charge held by the floating diffusion, and a selection transistor that controls a timing at which the pixel signal is outputted from the amplification transistor.

6. The imaging device according to claim 5, wherein
the amplification transistor and the reset transistor are formed in the second substrate, and
the selection transistor is formed in the third substrate.

7. The imaging device according to claim 5, wherein
the amplification transistor is formed in the second substrate, and
the reset transistor and the selection transistor are formed in the third substrate.

8. The imaging device according to claim 5, further comprising a fourth substrate having a seventh surface and an eighth surface and including a third transistor on a fourth semiconductor substrate, the third transistor configuring the pixel circuit, the fourth substrate being stacked on the third substrate with the sixth surface and the seventh surface being opposed to each other, wherein
the amplification transistor is formed in the second substrate,
the reset transistor is formed in the third substrate, and
the selection transistor is formed.

9. The imaging device according to claim 5, wherein a gate electrode of each of the transfer transistor, the reset transistor, the amplification transistor, and the selection transistor includes polysilicon or a metal material.

10. The imaging device according to claim 5, wherein a gate of the transfer transistor includes a metal material, and the gate of the transfer transistor and the floating diffusion are directly coupled to each other.

11. The imaging device according to claim 3, wherein one of a gate electrode, a source region, or a drain region of the first transistor and the pad electrode formed on the fourth surface are directly coupled to each other.

12. The imaging device according to claim 1, wherein the first transistor and the second transistor have a planar structure or a three-dimensional structure.

13. The imaging device according to claim 1, wherein a capacitor is further provided in the second substrate or the third substrate.

14. The imaging device according to claim 13, wherein
the sensor pixel includes a light-receiving element, a transfer transistor electrically coupled to the light-receiving element, and a floating diffusion that temporarily holds electric charge outputted from the light-receiving element through the transfer transistor,
the pixel circuit includes a reset transistor that resets an electric potential of the floating diffusion to a predetermined position, an amplification transistor that generates, as the pixel signal, a signal of a voltage corresponding to a level of the electric charge held by the floating diffusion, and a selection transistor that controls a timing at which the pixel signal is outputted from the amplification transistor, and
the capacitor is disposed between the floating diffusion and the amplification transistor.

15. The imaging device according to claim 14, further comprising a switching transistor that switches between coupling and decoupling of the capacitor.

16. The imaging device according to claim 14, wherein the capacitor has a metal-insulator-metal stacked structure or a metal-oxide-metal stacked structure.

17. The imaging device according to claim 1, wherein a resistor is further provided in the second substrate or the third substrate.

18. The imaging device according to claim 1, further comprising a fifth substrate having a ninth surface and a tenth surface and including a logic circuit on a fifth semiconductor substrate, the logic circuit processing the pixel signal, the fifth substrate being stacked over the third substrate with the ninth surface and the sixth surface being opposed to each other.

19. The imaging device according to claim 18, wherein the pixel circuit further includes an ADC circuit that converts an analog signal into a digital signal and holds the digital signal, the ADC circuit being provided in the fifth substrate.

20. The imaging device according to claim 19, wherein the sensor pixel provided in the first substrate, the first transistor provided in the second substrate, the second transistor provided in the third substrate, and the ADC circuit provided in the fifth substrate have formation areas that are substantially equal to each other.

21. The imaging device according to claim 19, wherein the ADC circuit includes one of a magnetoresistive memory, a resistance change memory, a ferroelectric memory, a phase change memory, or a flash memory.

22. The imaging device according to claim 1, wherein the first substrate and the second substrate, the first substrate and the third substrate, or the second substrate and the third substrate are electrically coupled to each other through a through wiring line that penetrates through one or both of the second semiconductor substrate and the third semiconductor substrate.

23. An electronic apparatus, comprising
an imaging device including:
a first substrate having a first surface and a second surface and including a sensor pixel on a first semiconductor substrate, the sensor pixel performing photoelectric conversion;
a second substrate having a third surface and a fourth surface and including a first transistor on a second semiconductor substrate, the first transistor configuring a pixel circuit that outputs a pixel signal based on electric charge outputted from the sensor pixel, the second substrate being stacked on the first substrate with the first surface and the third surface being opposed to each other; and
a third substrate having a fifth surface and a sixth surface and including a second transistor on a third semiconductor substrate, the second transistor configuring the pixel circuit, the third substrate being stacked on the second substrate with the fourth surface and the fifth surface being opposed to each other.
